(19) United States
(12) Patent Application Publication
(10) Pub. No.: US 2020/0388764 A1
(43) Pub. Date: Dec. 10, 2020

(54) COMPOUND, DISPLAY PANEL AND DISPLAY APPARATUS

(71) Applicant: Shanghai Tianma AM-OLED Co.,Ltd., Shanghai (CN)

(72) Inventors: Wenpeng Dai, Shanghai (CN); Wei Gao, Shanghai (CN); Jinghua Niu, Shanghai (CN); Lei Zhang, Shanghai (CN); Yan Lu, Shanghai (CN); Dongyang Deng, Shanghai (CN)

(21) Appl. No.: 16/669,398

(22) Filed: Oct. 30, 2019

(30) Foreign Application Priority Data
May 27, 2019 (CN) 201910446406.5

(51) Int. Cl. H01L 51/00

(52) U.S. Cl. CPC H01L 51/0052; H01L 51/0072; H01L 51/0067; H01L 51/5206; H01L 51/008; H01L 51/0065; H01L 51/0069; H01L 51/006

(57) ABSTRACT

The present disclosure relates to the field of OLED technologies, and provides a light-emitting host material including an adamantane structure, and having a structure represented by Formula (I). L₁ and L₂ are each independently selected from a single bond, phenyl, naphthyl or the like. The electron donor D is selected from carbazolyl and its derivative groups, diphenylamino and its derivative groups, or acridinyl and its derivative groups. The electron acceptor A is mainly selected from a nitrogen-containing heterocyclic substituent, a cyano-containing substituent, a triarylboron-based substituent. The D-(π)-σ-(π)-A structure in the compound has a bipolar property, and the intermediate σ bond can effectively interrupt the intramolecular charge transmission between the electron donor D and the electron acceptor A. The compound is used as a host material of the light-emitting layer in an OLED to reduce the efficiency roll-off of the blue light material, and enhance luminance and efficiency.

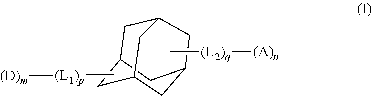

### CROSS-REFERENCE TO RELATED APPLICATIONS

The present application claims priority to Chinese Patent Application No. 201910446406.5, filed on May 27, 2019, the content of which is incorporated herein by reference in its entirety.

### TECHNICAL FIELD

The present disclosure relates to the field of organic electroluminescent materials, and particularly, to a compound suitable for use as a light-emitting host material of an OLED, a display panel including the compound, and a display apparatus.

### BACKGROUND

As a new generation of display technology, organic electroluminescent materials such as organic light-emitting diodes (OLED) have been widely applied in flat-panel displays, flexible displays, solid-state lighting and vehicle displays, due to their advantages of smaller thickness, self-illumination, wide viewing angle, fast response, high efficiency, good temperature adaptability, simple manufacturing process, low driving voltage, low energy consumption, and the like.

Electroluminescence can be classified into electrofluorescence and electrophosphorescence depending upon the luminescence mechanism. Fluorescence is a result of a radiation attenuation transition of singlet excitons, and phosphorescence is a result of light emitted during attenuation transition to the ground state of triplet excitons. According to the spin-statistics theory, a probability ratio of forming singlet excitons and triplet excitons is 1:3. The internal quantum efficiency of the electrofluorescent material is no more than 25%, and the external quantum efficiency is generally less than 5%. Theoretically, the internal quantum efficiency of the electrophosphorescent material can reach 100%, and the external quantum efficiency can be up to 20%. In 1998, Professor Yuguang Ma from Jilin University in China and Professor Forrest from Princeton University in the United States both reported that ruthenium complexes and platinum complexes were used as dyes doped into the light-emitting layer, a phenomenon of electrophosphorescence was explained, and applied the prepared phosphorescent material to an electroluminescent device.

The long lifetime (μs) of phosphorescent heavy metal materials may lead to triplet state-triplet state quenching and concentration quenching at high current densities and further result in a degradation of device performance. Therefore, phosphorescent heavy metal materials are usually doped into suitable host materials to form a host-guest doping system. In this way, energy transfer is enhanced, and light-emitting efficiency and lifetime are increased. At present, heavy metal doping materials have been commercialized; however, development of alternative doping materials has proven challenging. Thus, there is an urgent need to develop a novel phosphorescent host material.

### SUMMARY

In view of this, the present disclosure provides a compound having a structure of D-(π)-σ-(π)-A. The compound has a chemical structure according to Formula (I):

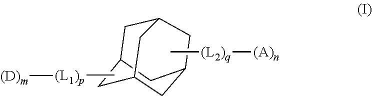

wherein D is an electron donor, and A is an electron acceptor; m is a number of D, n is a number of the A, and m and n are each an integer independently selected from 1, 2 or 3; p is a number of L₁, q is a number of L₂, and p and q are each an integer independently selected from 0, 1 or 2;

L₁ and L₂ are each independently selected from the group consisting of a single bond, a substituted or unsubstituted C1-C20 alkylene, a substituted or unsubstituted C3-C20 cycloalkylene, a substituted or unsubstituted C3-C20 heterocyclic alkylene, a substituted or unsubstituted C6-C40 arylene, a substituted or unsubstituted C4-C40 heteroarylene, a substituted or unsubstituted C10-C60 fused arylene, a substituted or unsubstituted C10-C60 fused heteroarylene, and combinations thereof;

D is selected from the group consisting of a substituted or unsubstituted C1-C20 alkyl, a substituted or unsubstituted C3-C20 cycloalkyl, a substituted or unsubstituted C1-C20 alkoxy, a substituted or unsubstituted C3-C20 heterocyclic group, a substituted or unsubstituted C6-C40 aryl, a substituted or unsubstituted C4-C40 heteroaryl, a substituted or unsubstituted C10-C60 fused aryl, a substituted or unsubstituted C10-C60 fused heteroaryl, a substituted or unsubstituted C12-C40 carbazolyl and its derivative groups, a substituted or unsubstituted C12-C40 diphenylamino and its derivative groups, a substituted or unsubstituted C18-C60 triphenylamino and its derivative groups, a substituted or unsubstituted C13-C40 acridinyl and its derivative groups, and combinations thereof; and

A is selected from the group consisting of a nitrogen-containing heterocyclic group, a cyano-containing group, a triarylboron-based group, a benzophenone-based group, a heteroaromatic ketone-based group, a sulfone-based group, a phosphoroso-containing groups, and combinations thereof.

The present disclosure further provides a display panel. The display panel includes an organic light-emitting device, the organic light-emitting device includes an anode, a cathode arranged opposite to the anode, and a light-emitting layer disposed between the anode and the cathode. The light-emitting layer includes a host material and a guest material, wherein the host material of the light-emitting layer is one or more of compounds according to the present disclosure.

The present disclosure further provides a display apparatus including the display panel according to the present disclosure.

### BRIEF DESCRIPTION OF DRAWINGS

FIG. 1 is a chemical formula of a compound according to an embodiment of the present disclosure;

FIG. 2 is a structural schematic diagram of an OLED according to an embodiment of the present disclosure; and

FIG. 3 is a schematic diagram of a display apparatus according to an embodiment of the present disclosure.

### DESCRIPTION OF EMBODIMENTS

The present disclosure is further described in combination with the following embodiments, which are merely intended to explain the present disclosure. The present disclosure is not limited to the following examples.

In a first aspect, the present disclosure provides a compound having a D-(π)-σ-(π)-A structure and a chemical structure according to Formula (I):

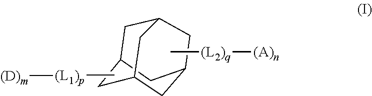

wherein D is an electron donor, and A is an electron acceptor; m is a number of D, n is a number of A, and m and n are each an integer independently selected from 1, 2 or 3; p is a number of L₁, q is a number of L₂, and p and q are each an integer independently selected from 0, 1 or 2;

L₁ and L₂ are each independently selected from the group consisting of a single bond, a substituted or unsubstituted C1-C20 alkylene, a substituted or unsubstituted C3-C20 cycloalkylene, a substituted or unsubstituted C3-C20 heterocyclic alkylene, a substituted or unsubstituted C6-C40 arylene, a substituted or unsubstituted C4-C40 heteroarylene, a substituted or unsubstituted C10-C60 fused arylene, a substituted or unsubstituted C10-C60 fused heteroarylene, and combinations thereof;

D is selected from the group consisting of a substituted or unsubstituted C1-C20 alkyl, a substituted or unsubstituted C3-C20 cycloalkyl, a substituted or unsubstituted C1-C20 alkoxy, a substituted or unsubstituted C3-C20 heterocyclic group, a substituted or unsubstituted C6-C40 aryl, a substituted or unsubstituted C4-C40 heteroaryl, a substituted or unsubstituted C10-C60 fused aryl, a substituted or unsubstituted C10-C60 fused heteroaryl, a substituted or unsubstituted C12-C40 carbazolyl and its derivative groups, a substituted or unsubstituted C12-C40 diphenylamino and its derivative groups, a substituted or unsubstituted C18-C60 triphenylamino and its derivative groups, a substituted or unsubstituted C13-C40 acridinyl and its derivative groups, and combinations thereof; and

A is selected from the group consisting of a nitrogen-containing heterocyclic group, a cyano-containing group, a triarylboron-based group, a benzophenone-based group, a heteroaromatic ketone-based group, a sulfone-based group, a phosphoroso-containing groups, and combinations thereof.

The compound provided by the present disclosure is a bipolar material and has a D-(π)-σ-(π)-A structure, which can replace the traditional D-π-A skeleton. The traditional D-π-A bipolar material has strong intramolecular charge transmission, resulting in a large dipole moment, μs. The D-(π)-σ-(π)-A structure of the compound according to the present disclosure is also bipolar, and the central σ bond can effectively interrupt the transmission between the electron donor D and the electron acceptor A, such that an excited state is limited as a local excited state within a segment of donor D or acceptor A. Therefore, the compound has a smaller excited state dipole moment, and the luminance and light-emitting efficiency is improved when the compound is used as a host material of a light-emitting layer of an OLED.

When the compound provided by the present disclosure is used as the host material in an organic light-emitting device, it can effectively improve the balanced migration of carriers, widen the exciton recombination region, and effectively improve the light extraction efficiency due to its high triplet energy level ET, great molecular density, high glass transition temperature and high molecular thermal stability, thereby enhancing the light-emitting efficiency of the device.

In addition, adamantane has is a chair-like structural unit of cyclohexane, and the entire ring structure is symmetrical and rigid, and is structurally order and highly stable. Therefore, when the compound of the present disclosure is used as a light-emitting host material in an OLED device, the service time will be significantly prolonged, so that it can be suitably applied in the field of electroluminescent devices.

According to an embodiment of the present disclosure, the compound has any one of the following chemical structures:

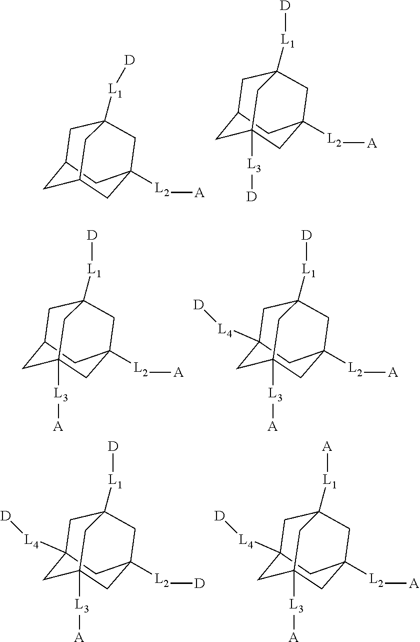

wherein L₃ and L₄ are each independently selected from the group consisting of a single bond, a substituted or unsubstituted C1-C20 alkylene, a substituted or unsubstituted C3-C20 cycloalkylene, a substituted or unsubstituted C3-C20 heterocyclic alkylene, a substituted or unsubstituted C6-C40 arylene, a substituted or unsubstituted C4-C40 heteroarylene, a substituted or unsubstituted C10-C60 fused arylene, a substituted or unsubstituted C10-C60 fused heteroarylene, and combinations thereof.

According to an embodiment of the present disclosure, D is according to any one of the following formulas:

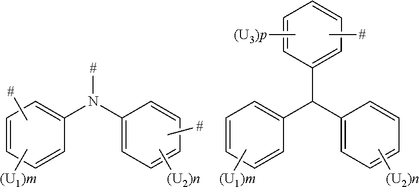

wherein m, n and p are each an integer independently selected from 0, 1, 2 or 3;

U₁, U₂, U₃ are each independently selected from the group consisting of a hydrogen atom, a substituted or unsubstituted C1-C30 alkyl, a substituted or unsubstituted silylene, a substituted or unsubstituted C3-C20 cycloalkyl, a substituted or unsubstituted C1-C30 alkoxy, a substituted or unsubstituted C6-C30 aryl, a substituted or unsubstituted C10-C30 fused aryl, and combinations thereof; and

# indicates a bonding position.

According to an embodiment of the present disclosure, D is according to any one of the following formulas:

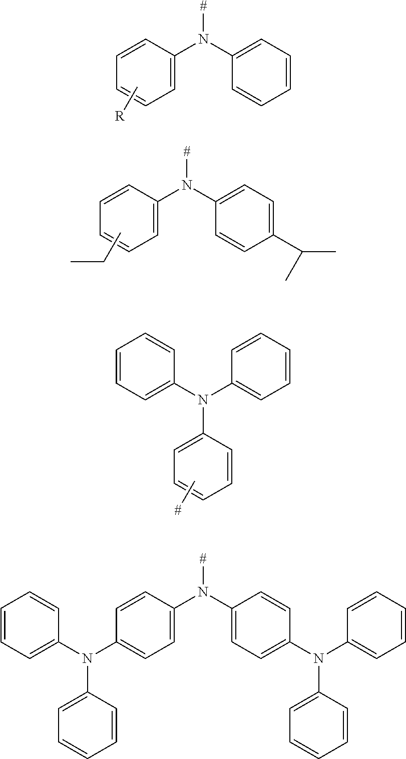

wherein R is selected from the group consisting of a hydrogen atom, a substituted or unsubstituted C1-C20 alkyl, a substituted or unsubstituted silylene group, a substituted or unsubstituted C3-C20 cycloalkyl, a substituted or unsubstituted C1-C20 alkane An oxy, a substituted or unsubstituted C3-C20 heterocyclic group, a substituted or unsubstituted C6-C40 aryl, a substituted or unsubstituted C10-C30 fused aryl, and a substituted or unsubstituted C4-C40 heteroaryl.

According to an embodiment of the present disclosure, D is according to any one of the following formulas:

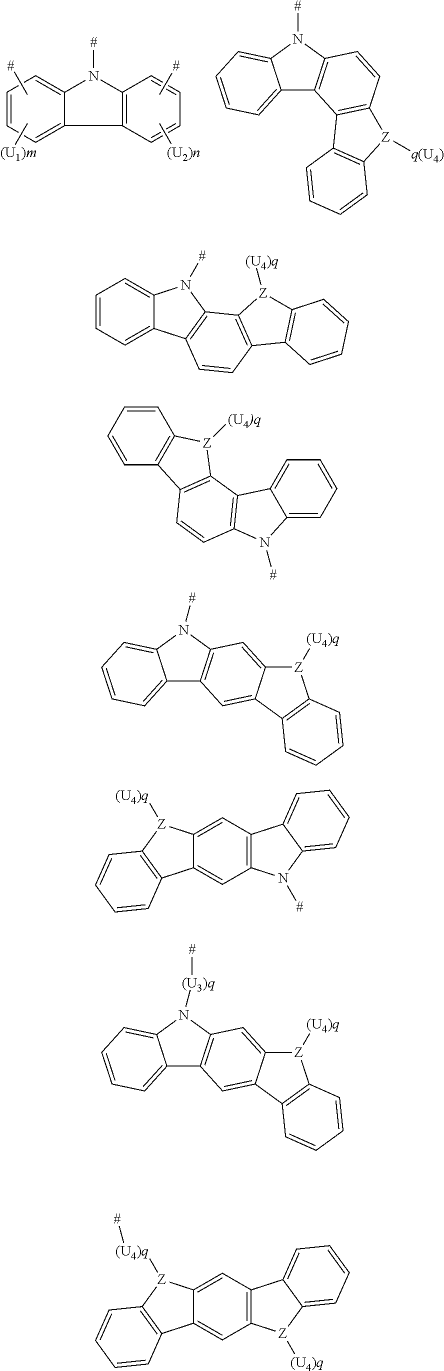

wherein

Z is selected from the group consisting of a carbon atom, a nitrogen atom, an oxygen atom, a sulfur atom and a silicon atom;

m, n and q are each an integer independently selected from 0, 1, 2 or 3;

U₁, U₂, U₃ and U₄ are each independently selected from the group consisting of a hydrogen atom, a substituted or unsubstituted C1-C30 alkyl, a substituted or unsubstituted silylene, a substituted or unsubstituted C3-C20 cycloalkyl, a substituted or unsubstituted C1-C30 alkoxy, a substituted or unsubstituted C6-C30 aryl, a substituted or unsubstituted C10-C30 fused aryl, and combinations thereof;

when Z is an oxygen atom or a sulfur atom, q is 0; and

# indicates a bonding position.

According to an embodiment of the present disclosure, D is according to any one of the following formulas:

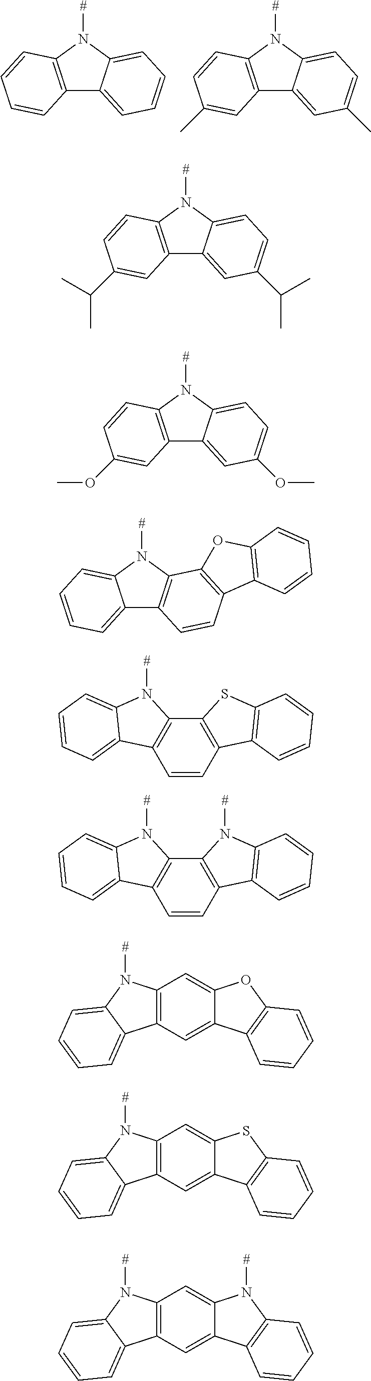

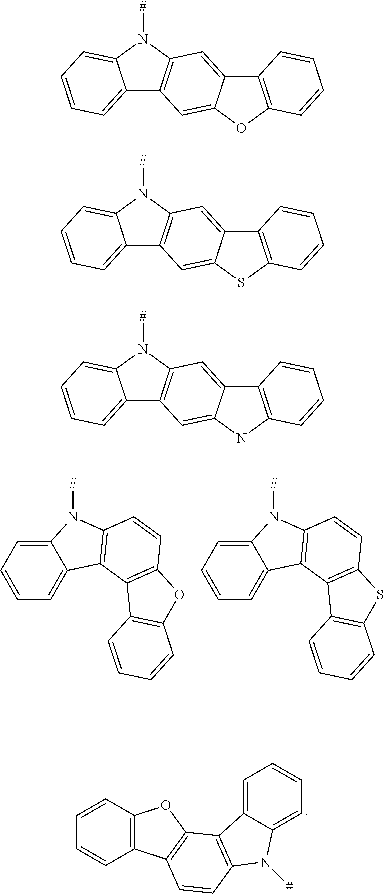

According to an embodiment of the present disclosure, D is according to any one of the following formulas:

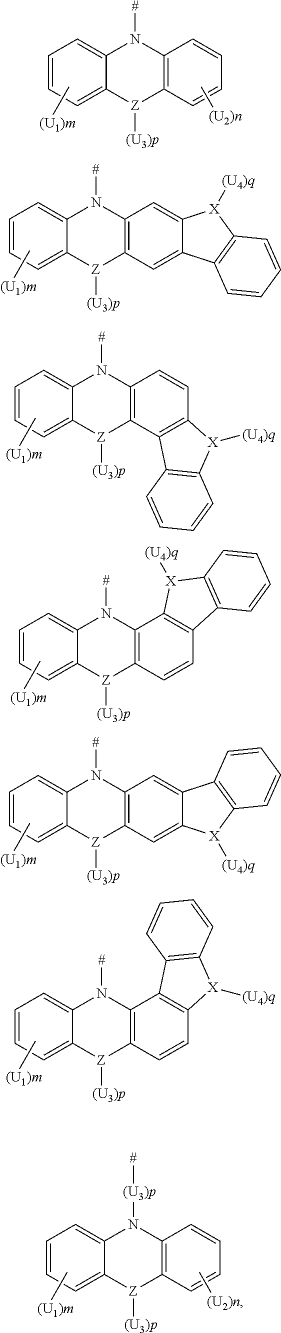

wherein

Z is selected from the group consisting of a carbon atom, a nitrogen atom, an oxygen atom, a sulfur atom and a silicon atom;

X is selected from the group consisting of a carbon atom, a nitrogen atom, an oxygen atom and a sulfur atom;

m, n, p and q are each an integer independently selected from 0, 1, 2 or 3;

U₁, U₂, U₃ and U₄ are each independently selected from the group consisting of a hydrogen atom, a substituted or unsubstituted C1-C30 alkyl, a substituted or unsubstituted silylene, a substituted or unsubstituted C3-C20 cycloalkyl, a substituted or unsubstituted C1-C30 alkoxy, a substituted or unsubstituted C6-C30 aryl, and a substituted or unsubstituted C10-C30 fused aryl, and combinations thereof;

when Z is an oxygen atom or a sulfur atom, p is 0;

when X is an oxygen atom or a sulfur atom, q is 0; and

# indicates a bonding position.

According to an embodiment of the present disclosure, D is according to any one of the following formulas:

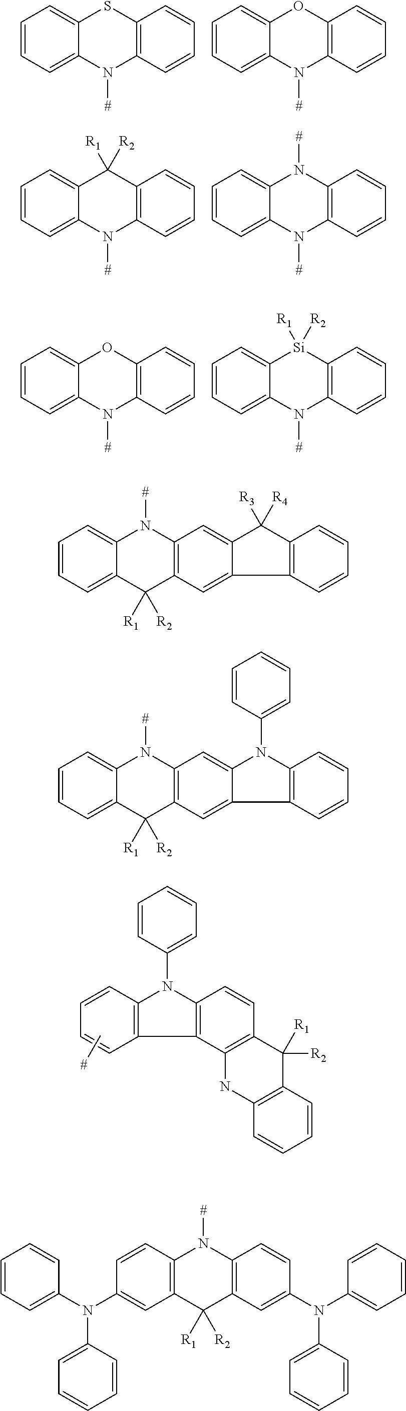

wherein

R₁, R₂, R₃ and R₄ are each independently selected from the group consisting of a hydrogenatom, a substituted or unsubstituted C1-C20 alkyl, a substituted or unsubstituted C3-C20 cycloalkyl, a substituted or unsubstituted C1-C20 alkoxy, a substituted or unsubstituted C3-C20 heterocyclic group, a substituted or unsubstituted C6-C40 aryl, and a substituted or unsubstituted C4-C40 heteroaryl.

According to an embodiment of the present disclosure, A is according to any one of the following formulas:

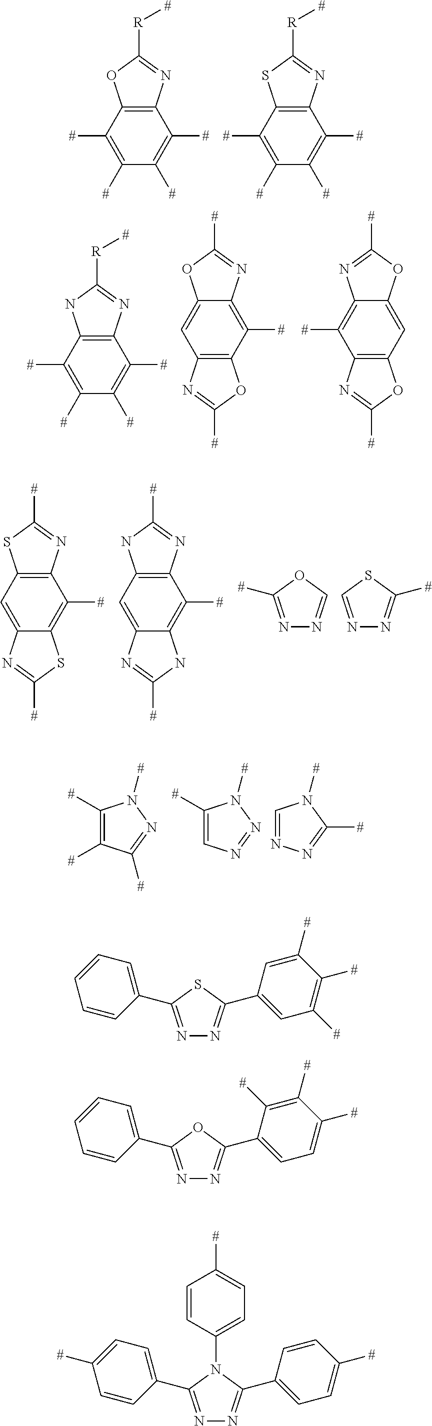

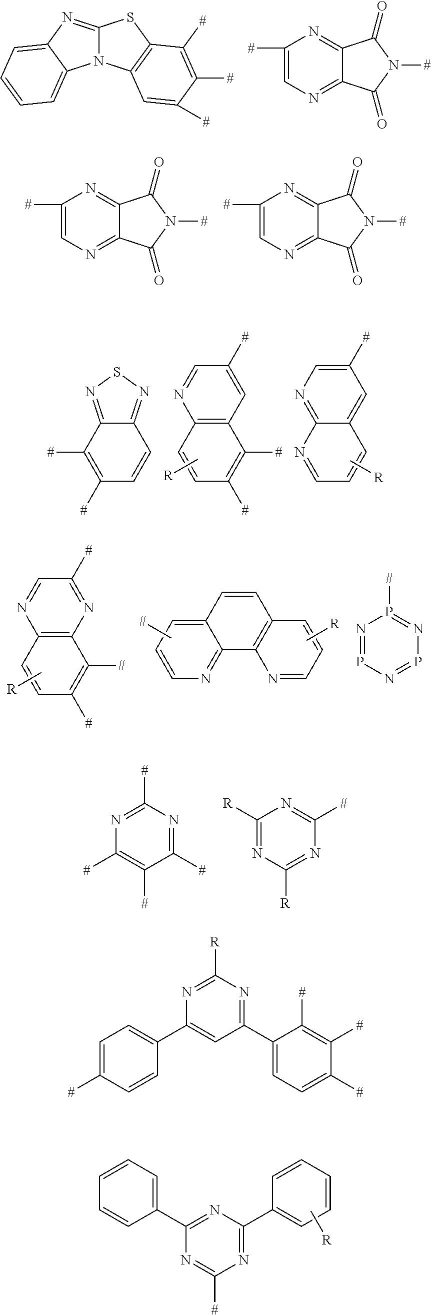

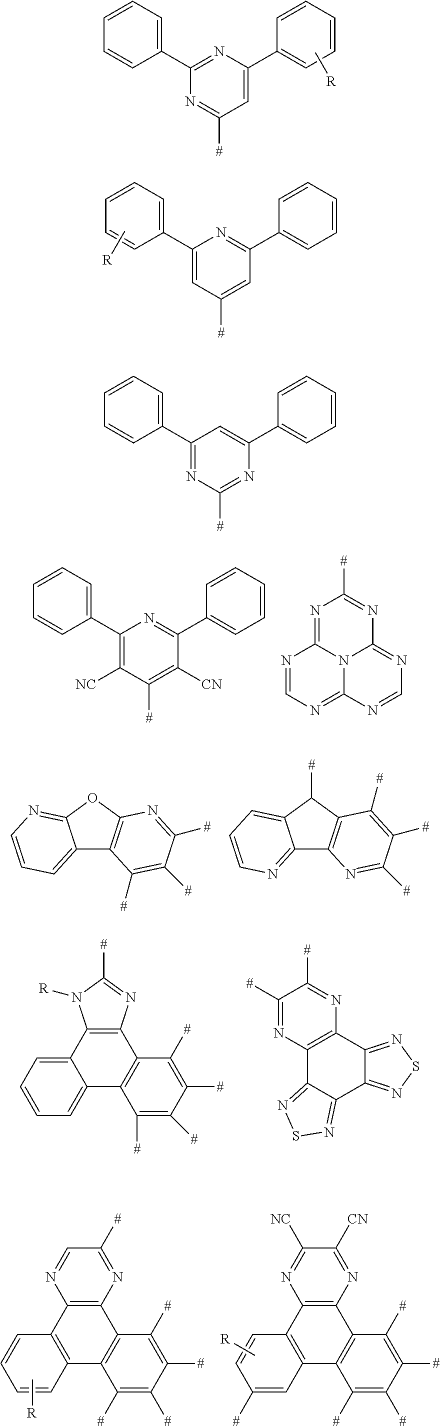

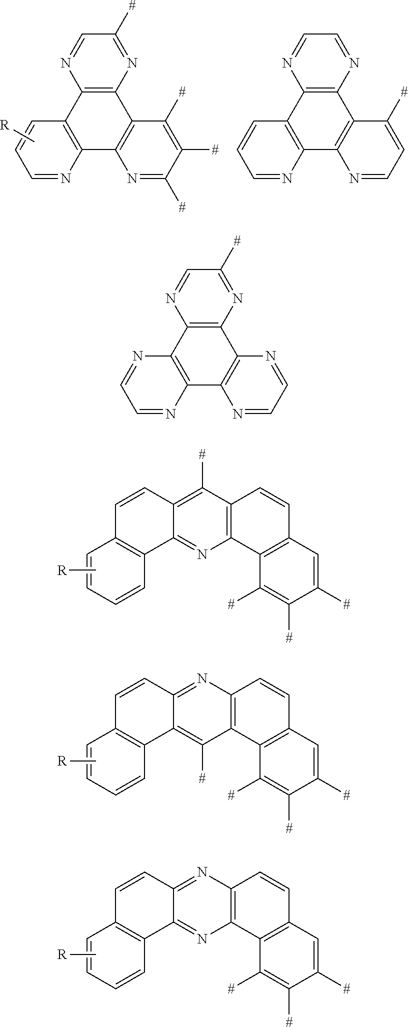

wherein R is selected from the group consisting of a hydrogen atom, a C1-C20 alkyl, a C1-C20 alkoxy, a C4-C8 cycloalkyl, a C6-C40 aryl, and a C4-C40 heteroaryl; and

# indicates a bonding position.

According to an embodiment of the present disclosure, A is according to any one of the following formulas:

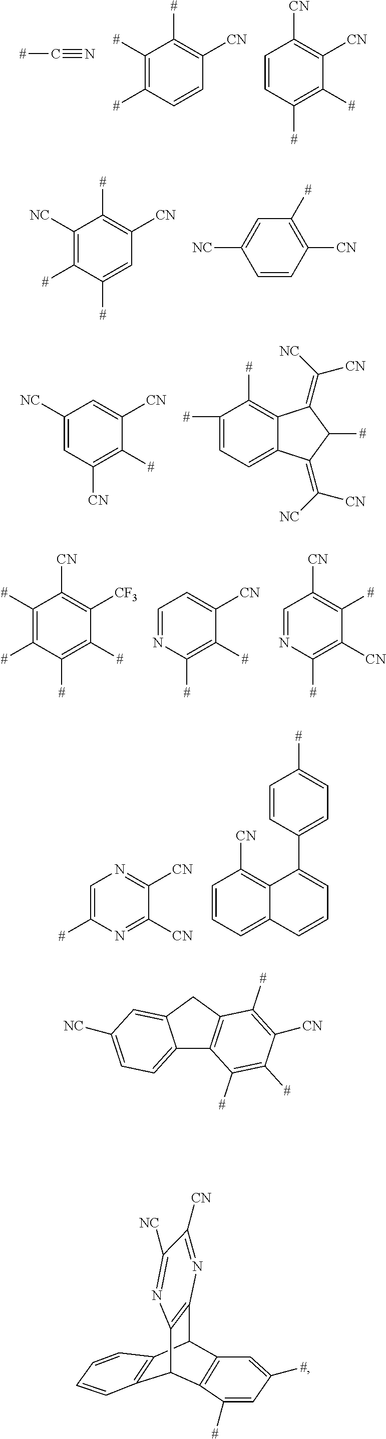

wherein # indicates a bonding position.

According to an embodiment of the present disclosure, A is according to any one of the following formulas:

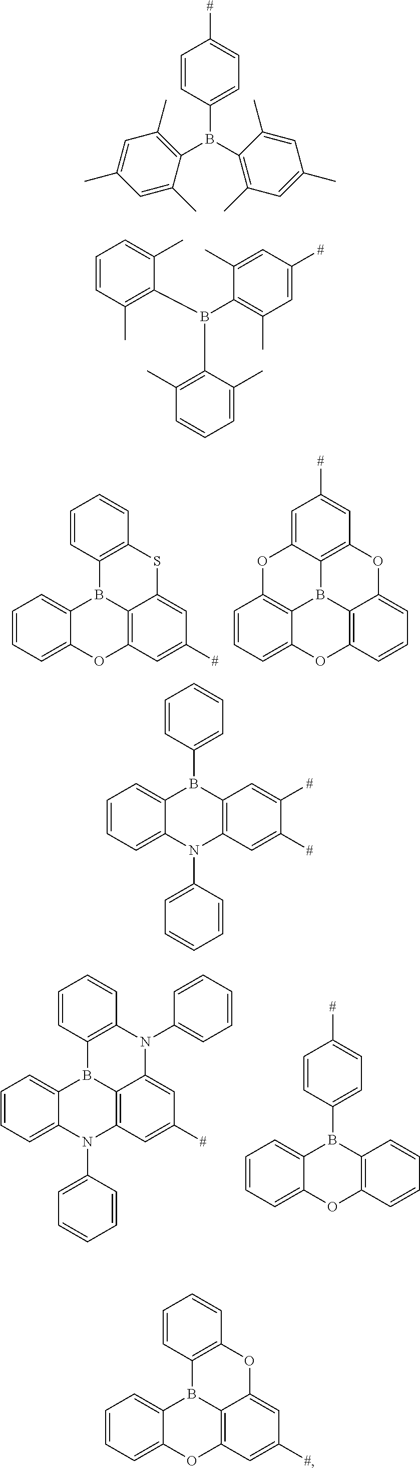

wherein # indicates a bonding position.

According to an embodiment of the present disclosure, A is according to any one of the following formulas:

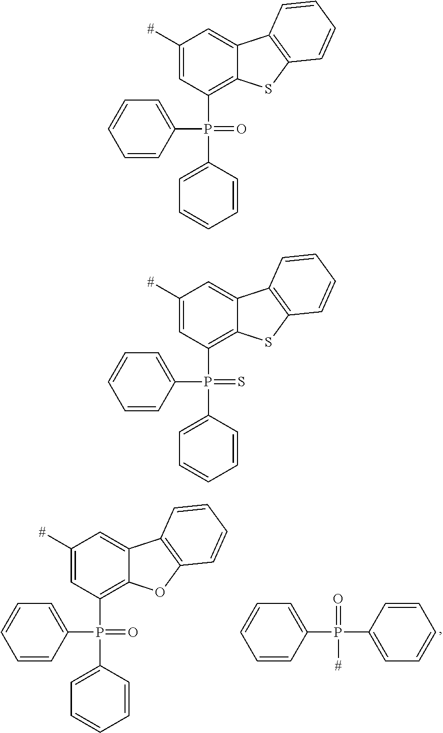

wherein # indicates a bonding position.

According to an embodiment of the present disclosure, L₁ and L₂ are each independently according to any one of the following formulas:

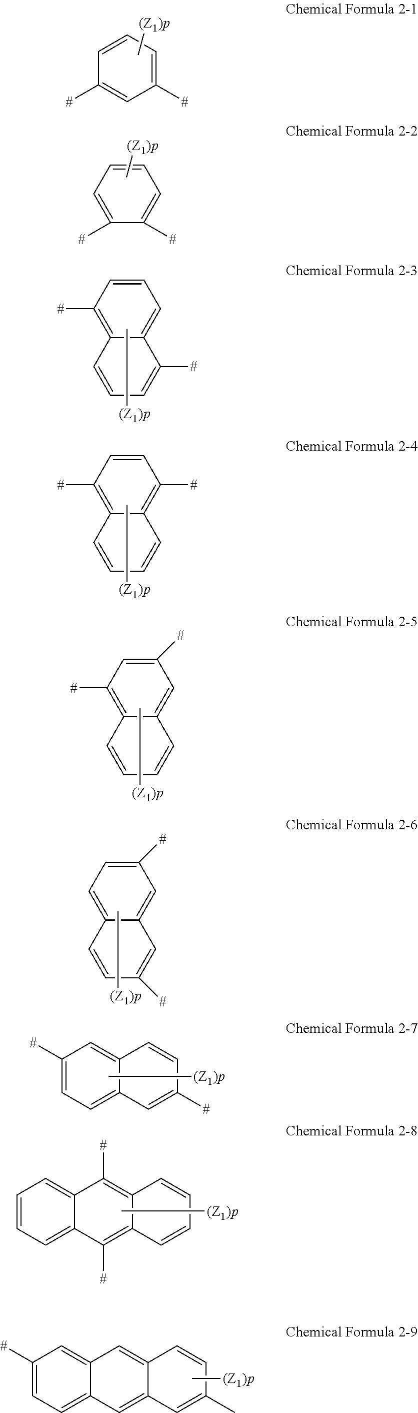

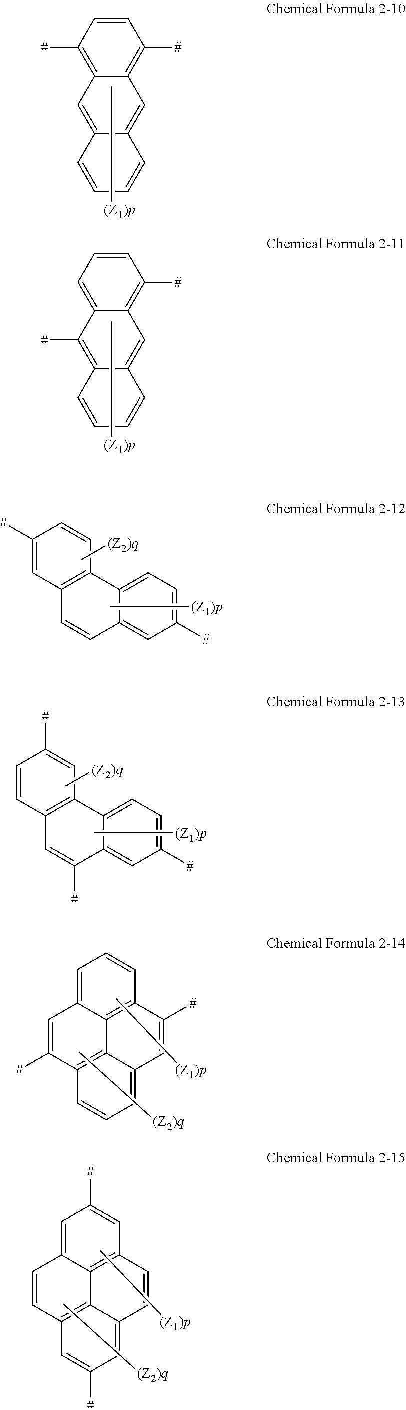

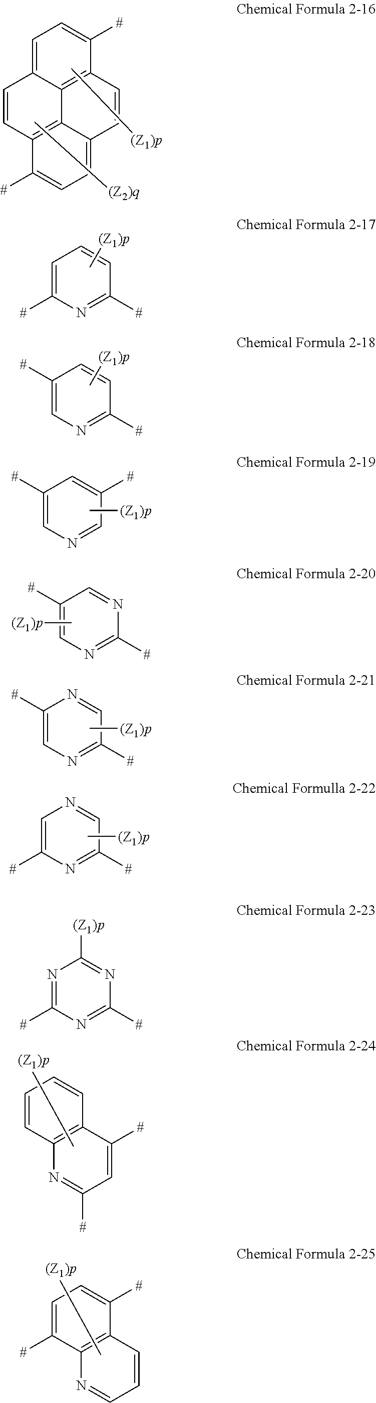

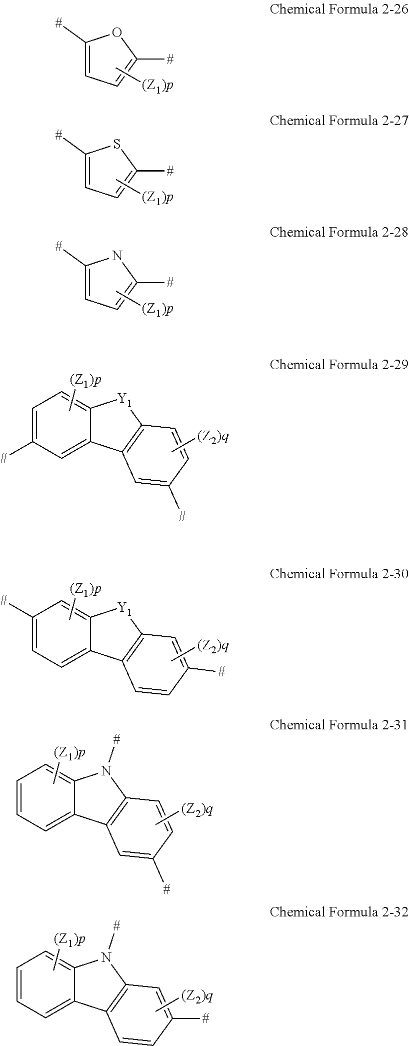

wherein

Z₁ and Z₂ are each independently selected from the group consisting of a hydrogen atom, a substituted or unsubstituted C6-C30 aryl, a substituted or unsubstituted C6-C30 fused aryl, and a substituted or unsubstituted C6-C30 fused heteroaryl;

p and q are each an integer greater than or equal to 0; and

# indicates a bonding position.

According to an embodiment of the present disclosure, L₁ and L₂ are each independently any one of the following structures:

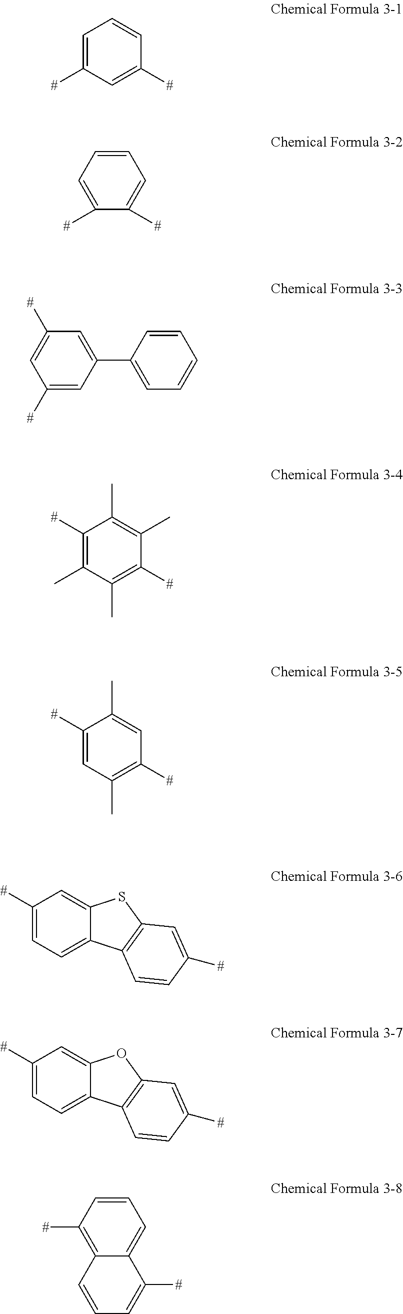

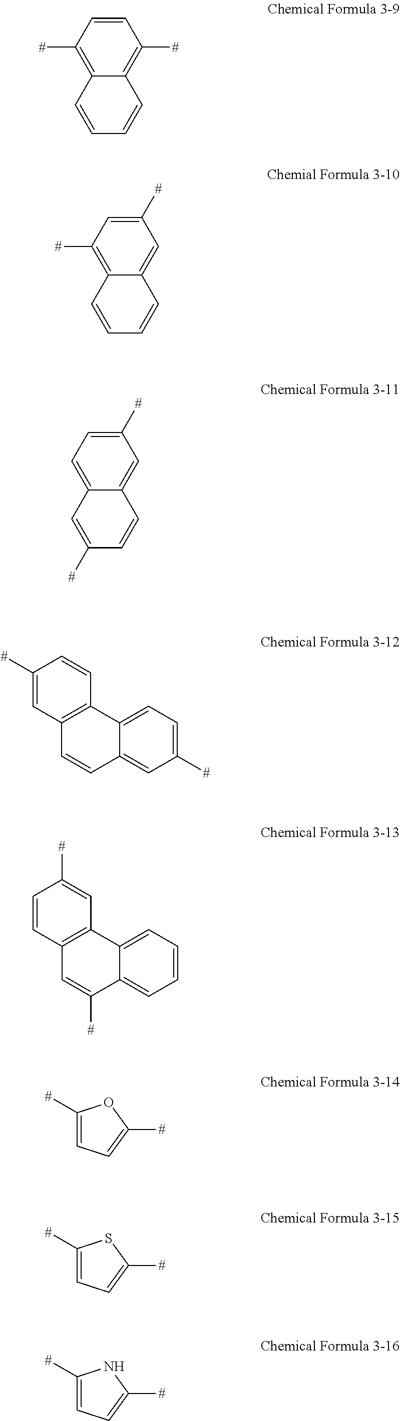

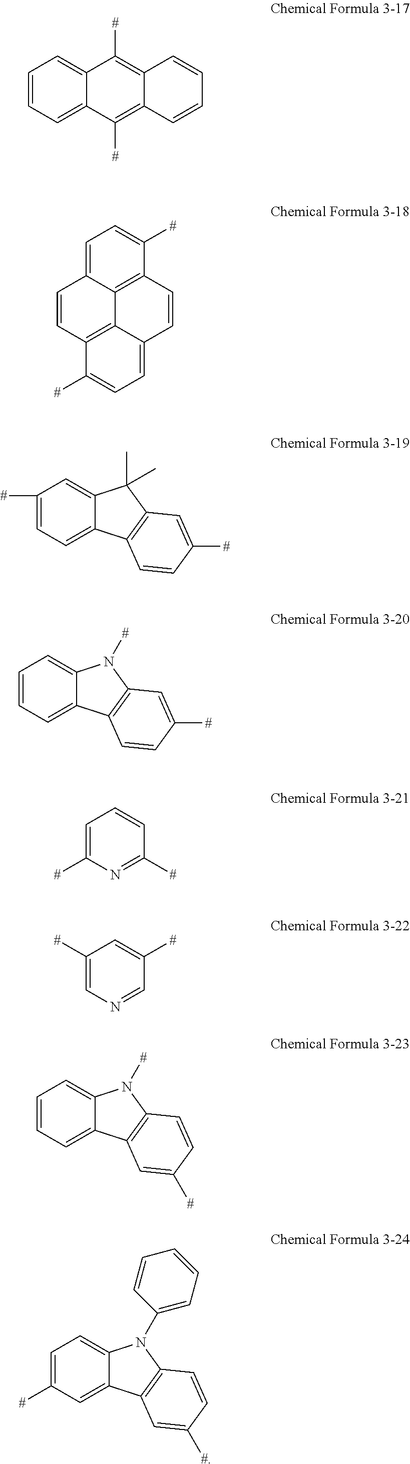

wherein # indicates a bonding position.

According to an embodiment of the present disclosure, the compound is selected from the group consisting of

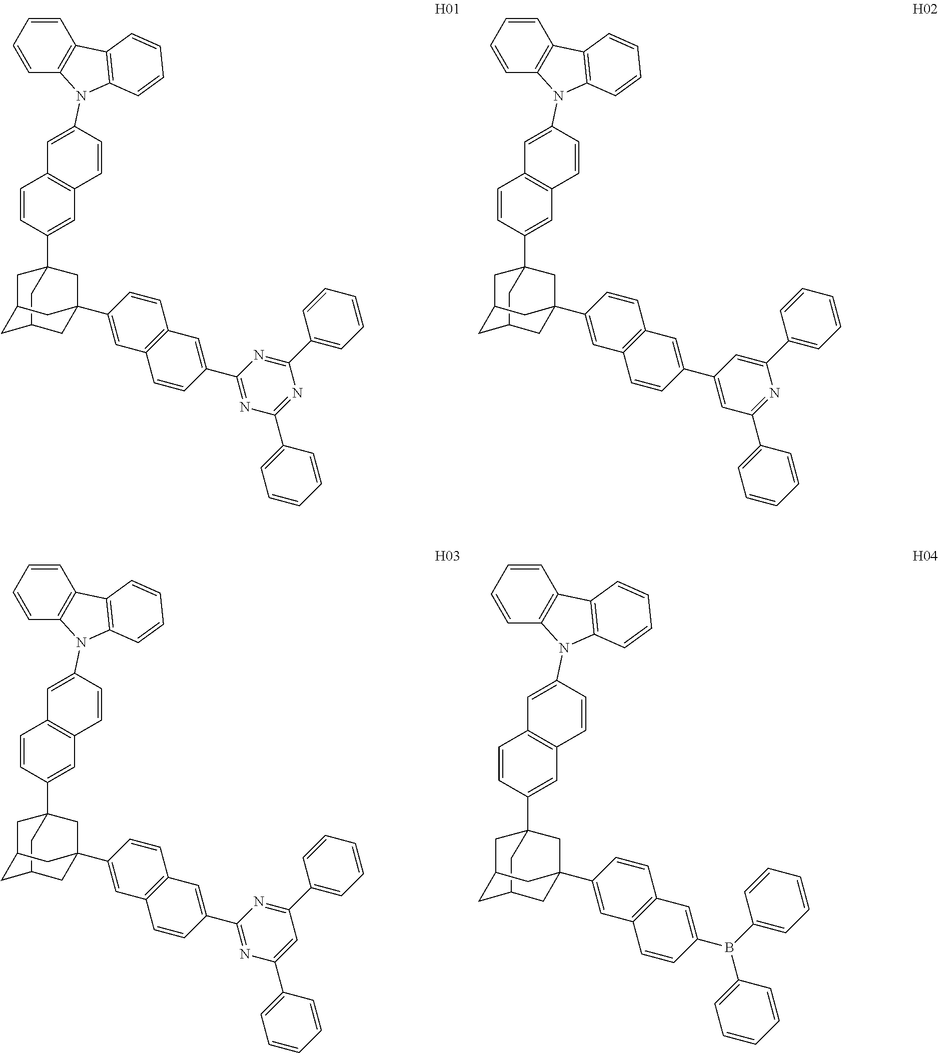 [SMILES: c1ccc(-c2nc(-c3ccccc3)nc(-c3ccc4cc(C56CC7CC(C5)CC(c5ccc8cc(-n9c%10ccccc%10c%10ccccc%109)ccc8c5)(C7)C6)ccc4c3)n2)cc1 ; c1ccc(-c2cc(-c3ccc4cc(C56CC7CC(C5)CC(c5ccc8cc(-n9c%10ccccc%10c%10ccccc%109)ccc8c5)(C7)C6)ccc4c3)cc(-c3ccccc3)n2)cc1 ; c1ccc(-c2cc(-c3ccccc3)nc(-c3ccc4cc(C56CC7CC(C5)CC(c5ccc8cc(-n9c%10ccccc%10c%10ccccc%109)ccc8c5)(C7)C6)ccc4c3)n2)cc1 ; c1ccc(B(c2ccccc2)c2ccc3cc(C45CC6CC(C4)CC(c4ccc7cc(-n8c9ccccc9c9ccccc98)ccc7c4)(C6)C5)ccc3c2)cc1]

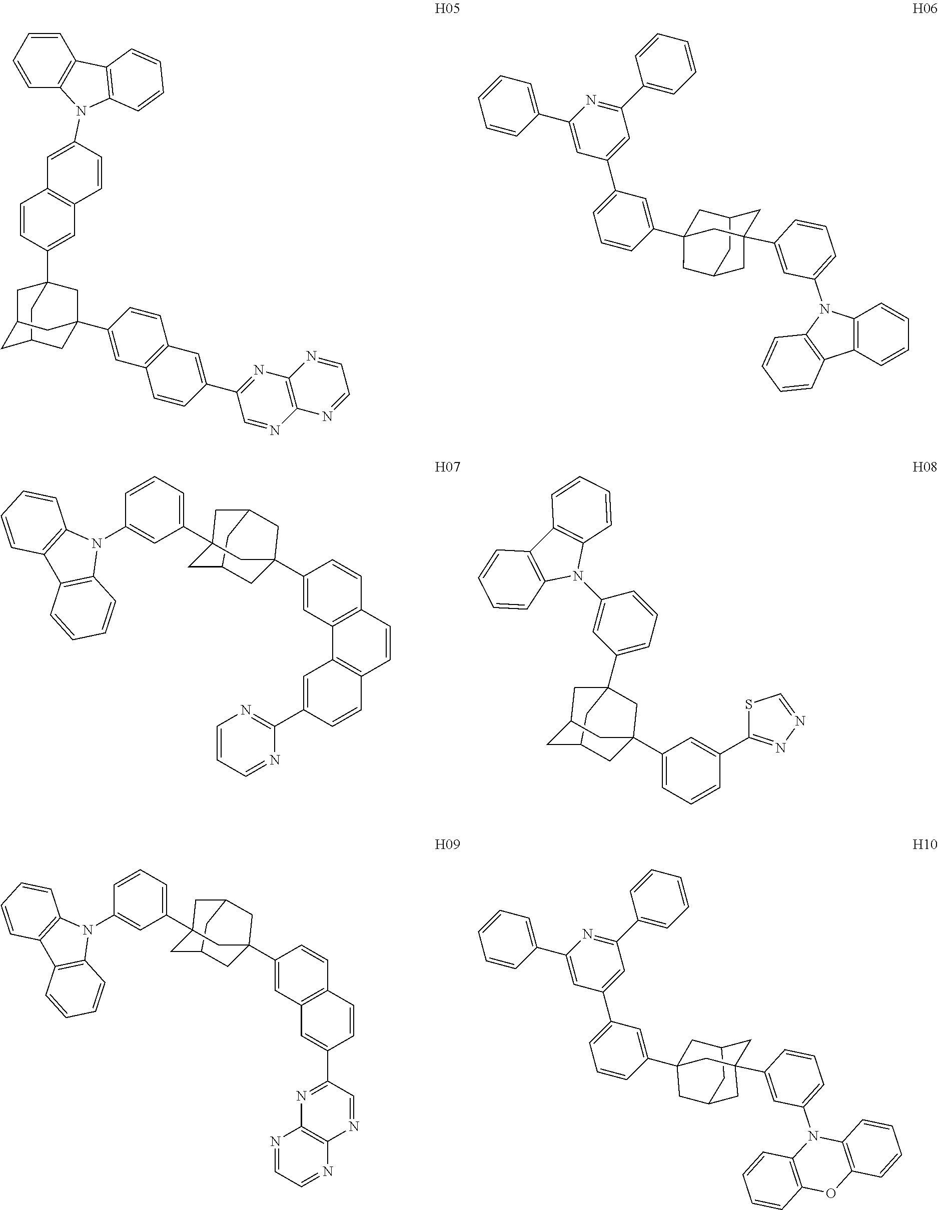

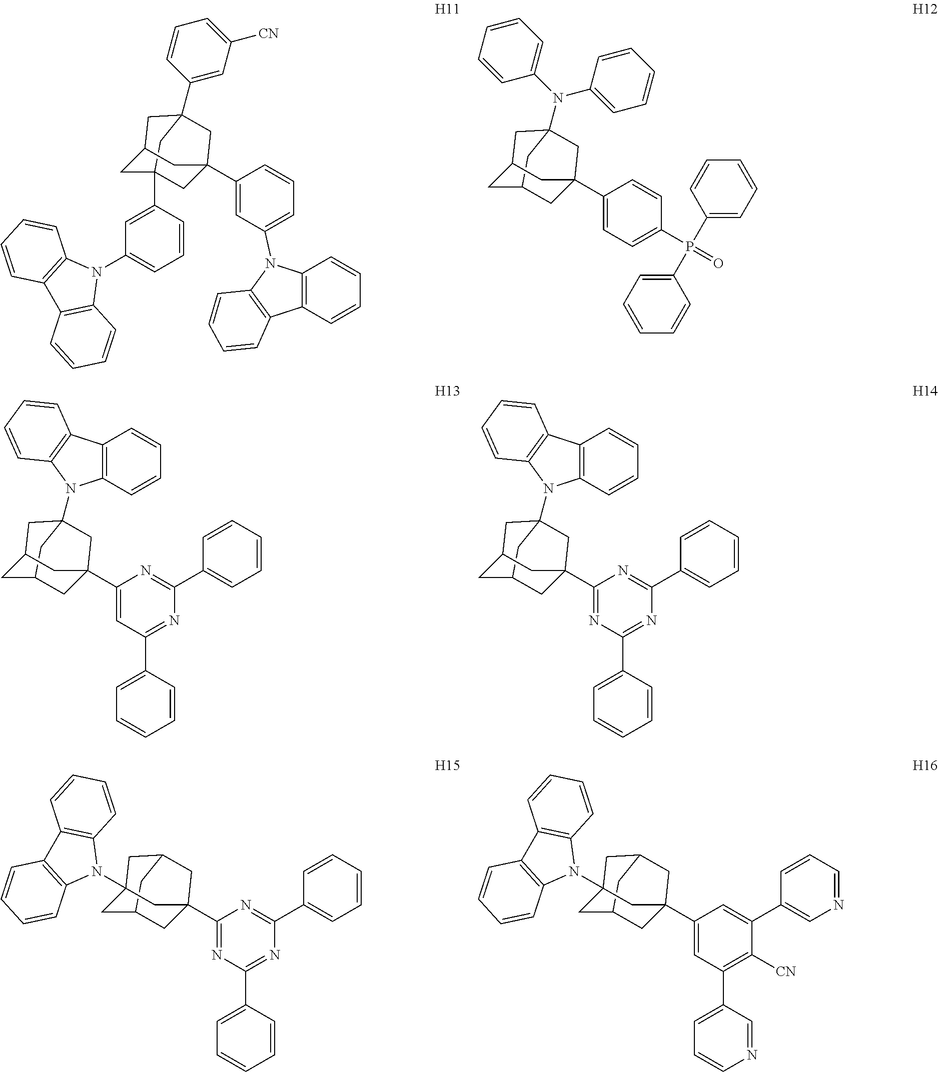

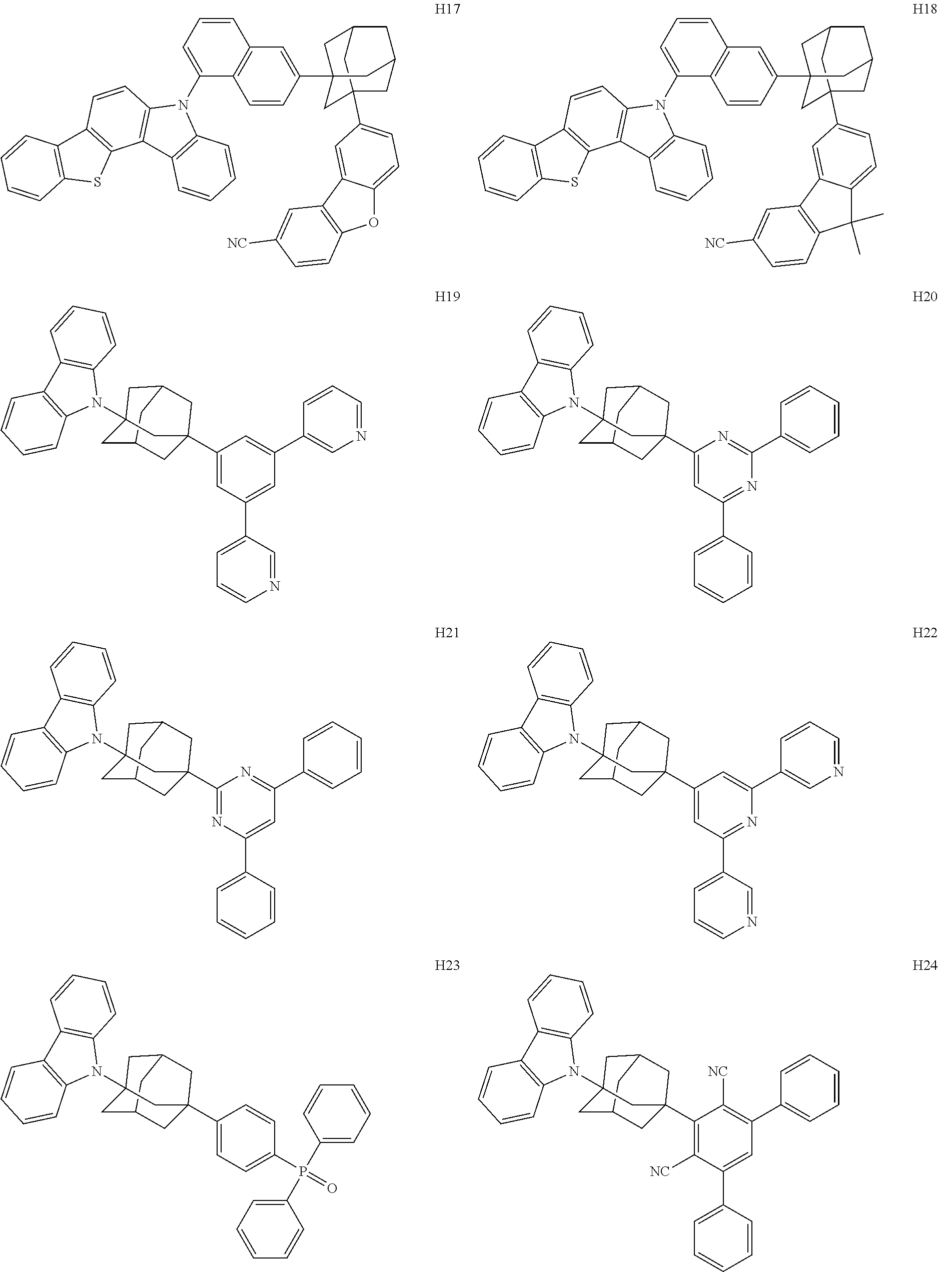

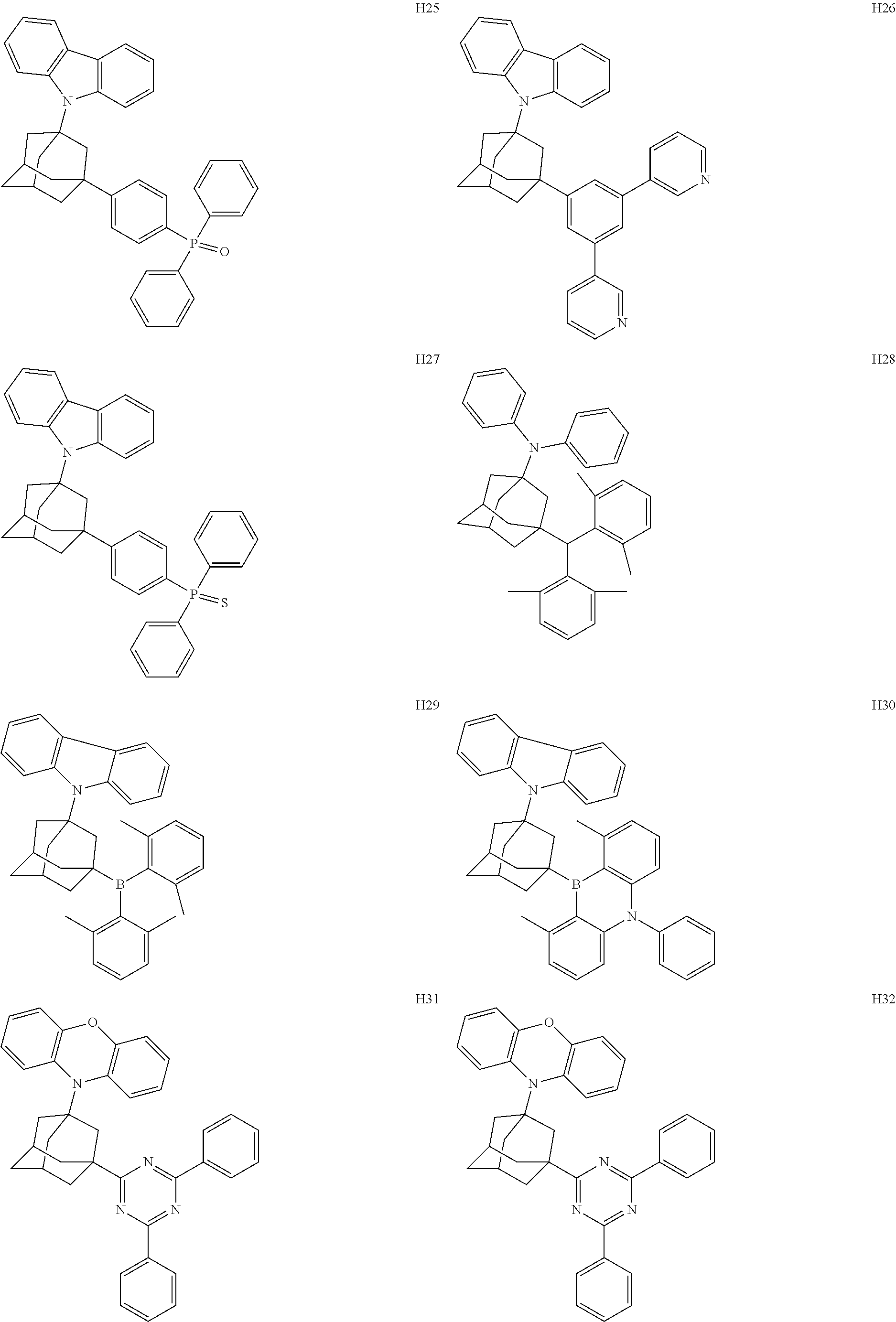

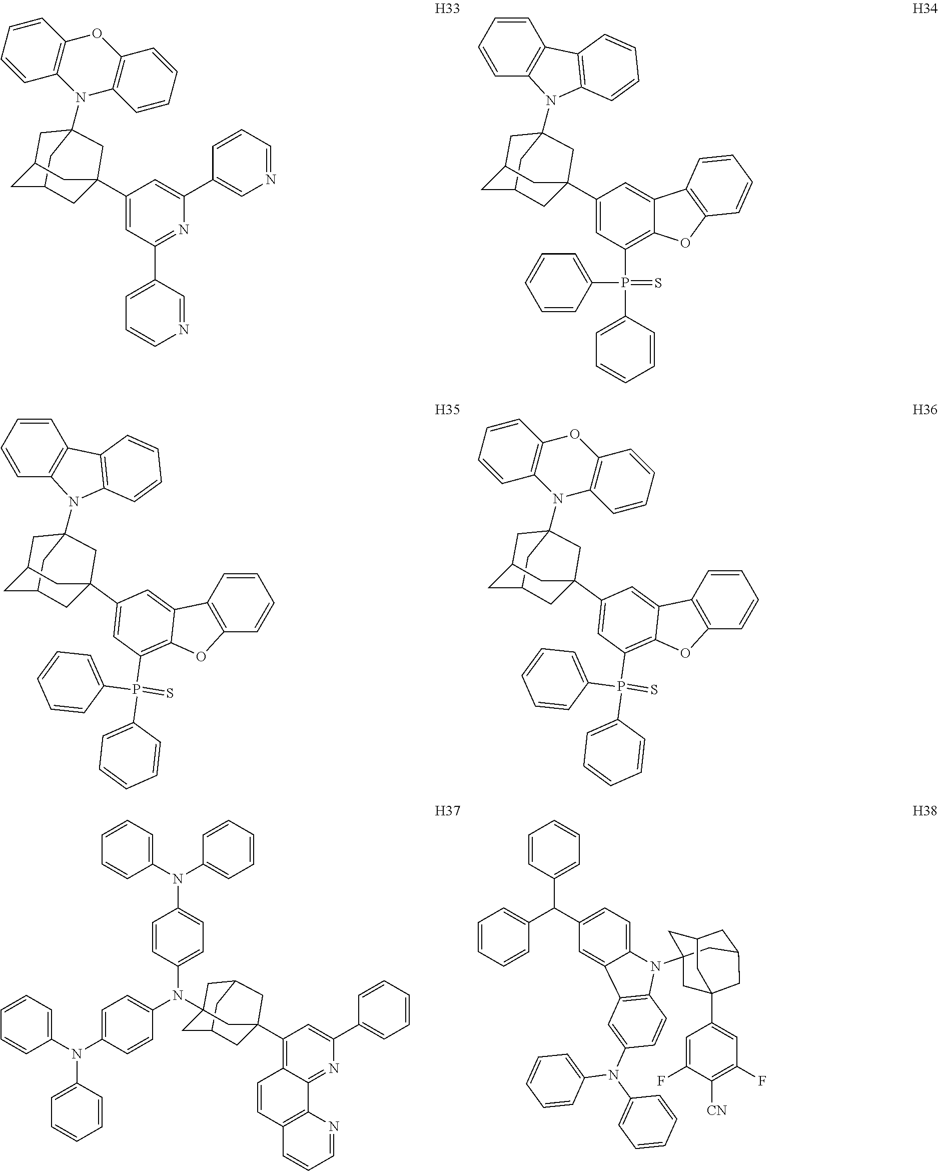

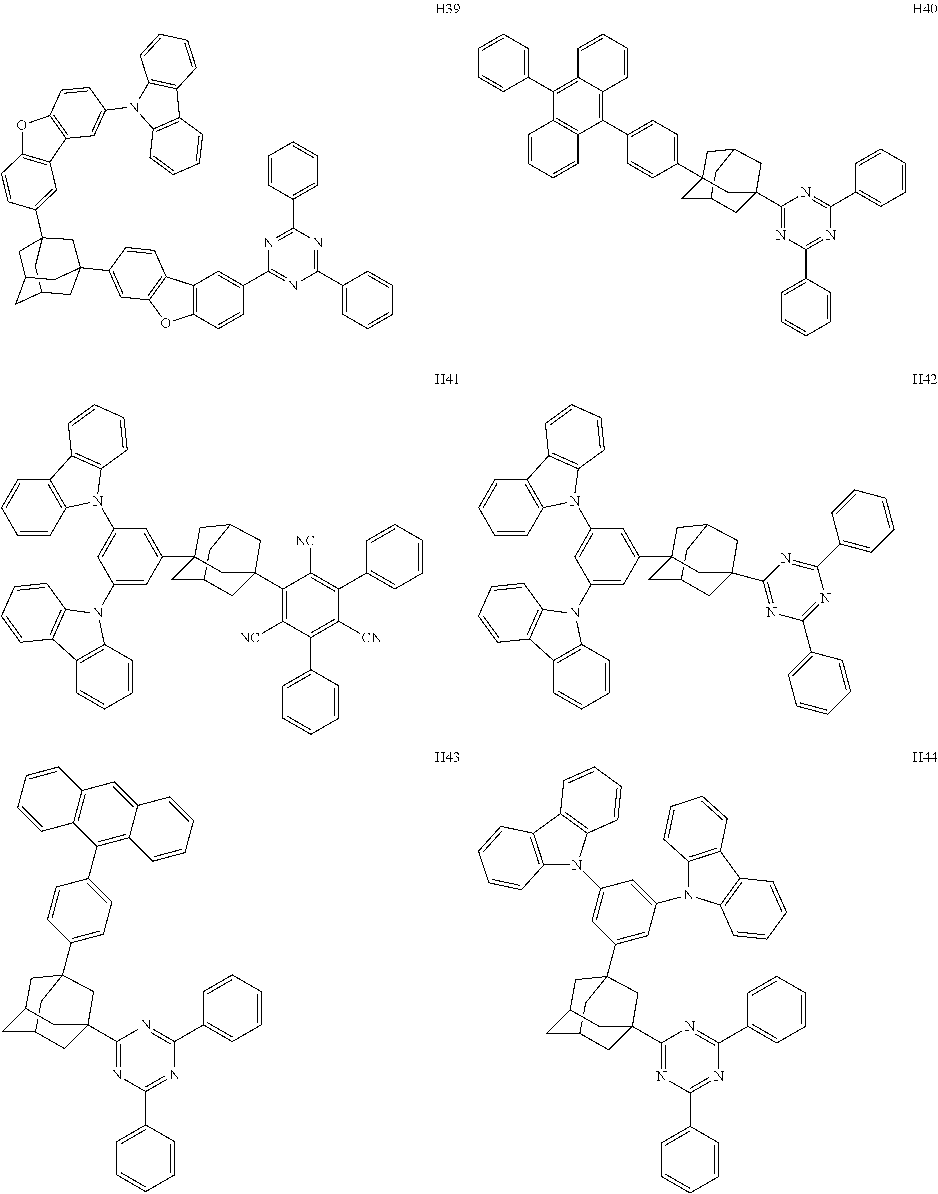

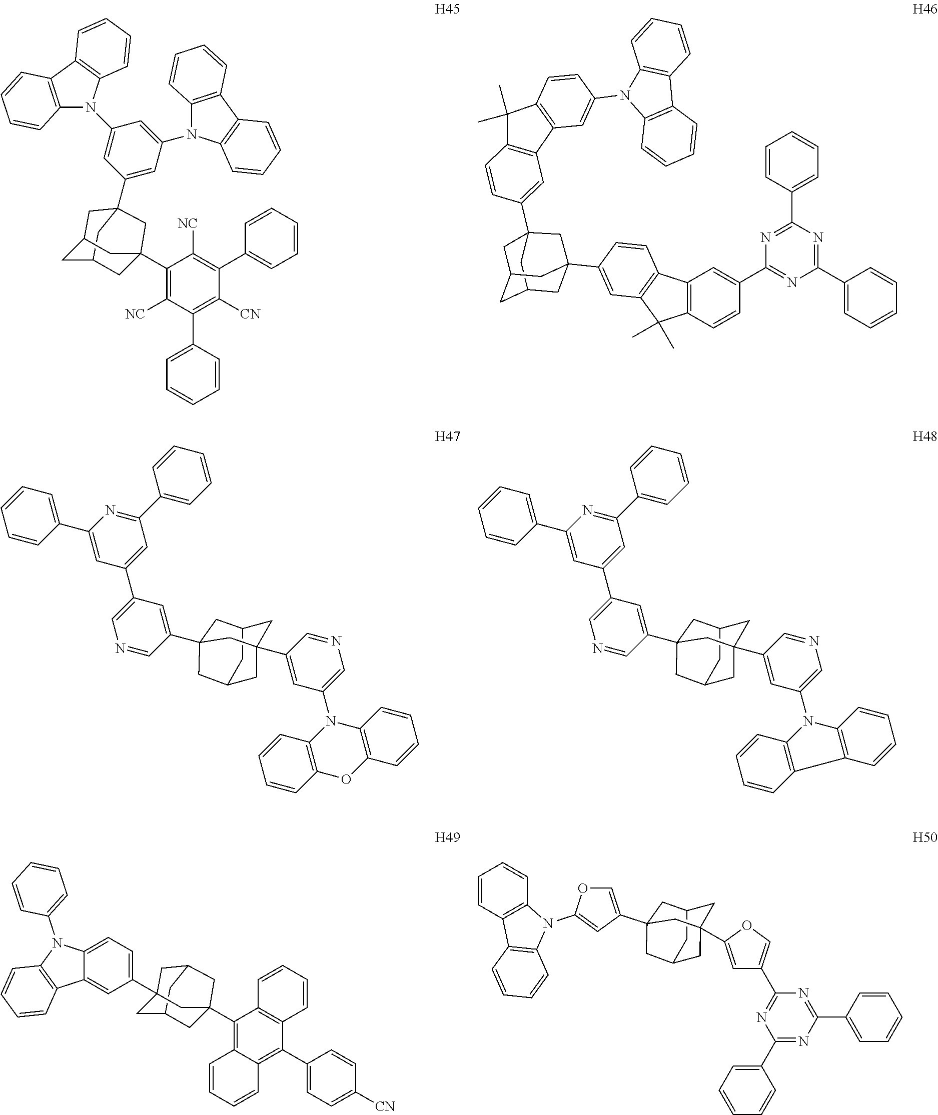

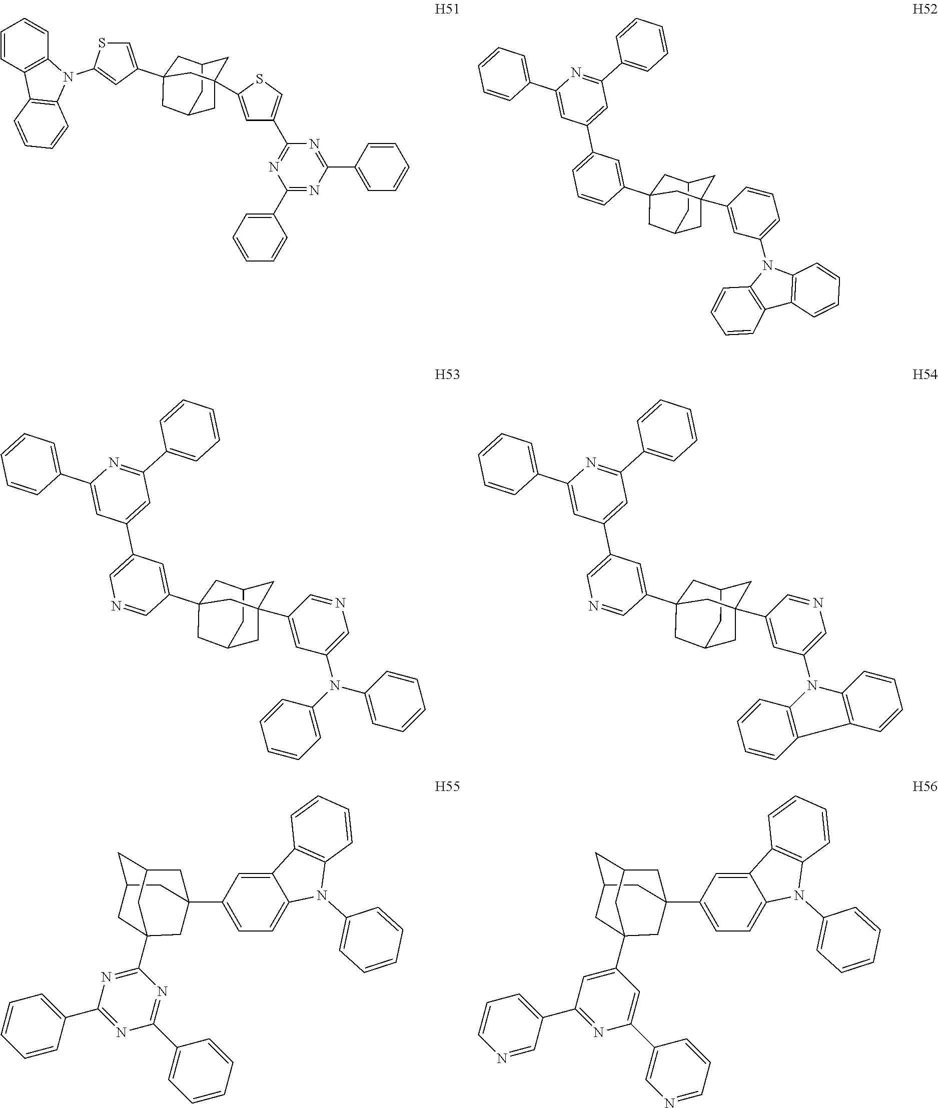

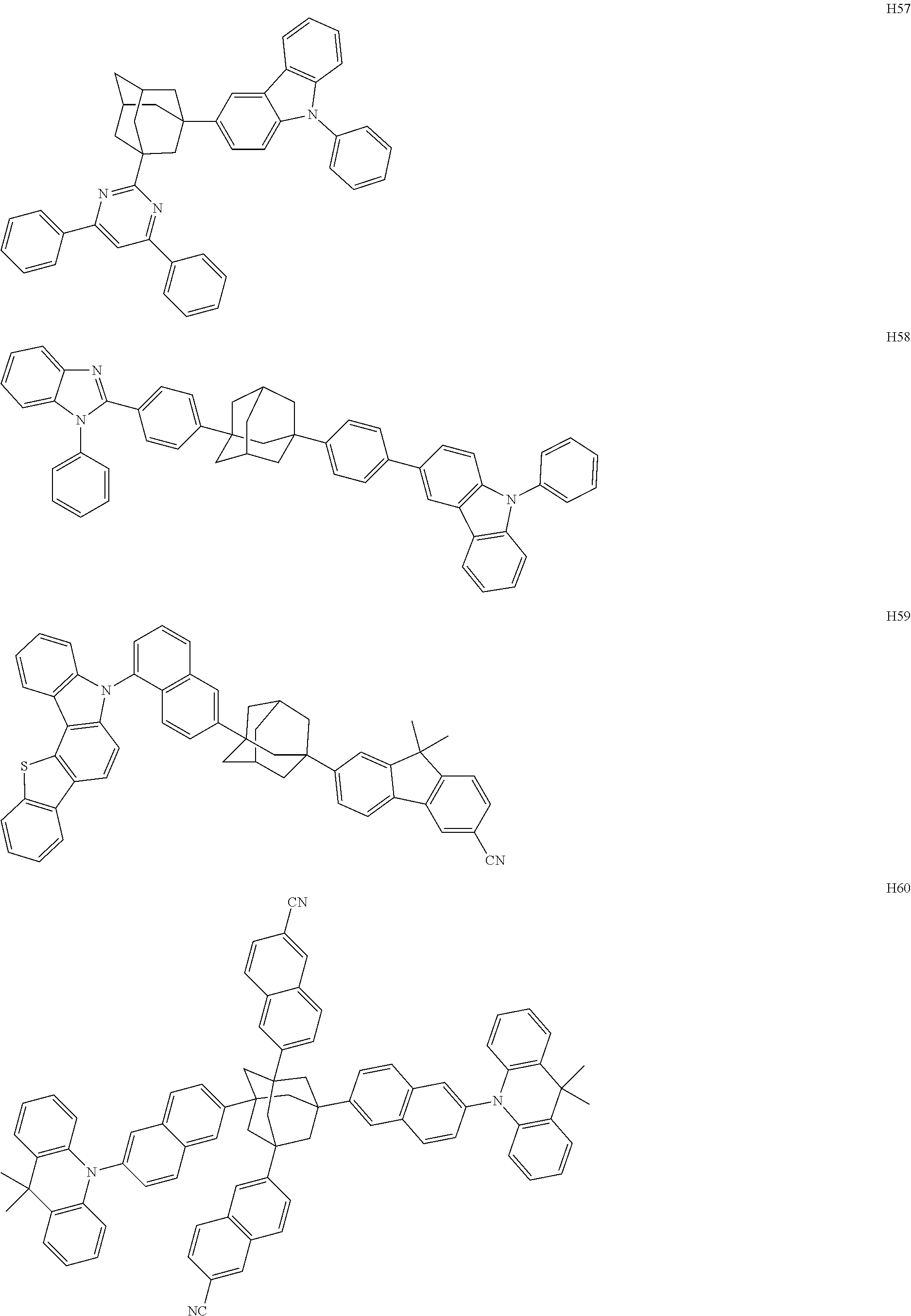

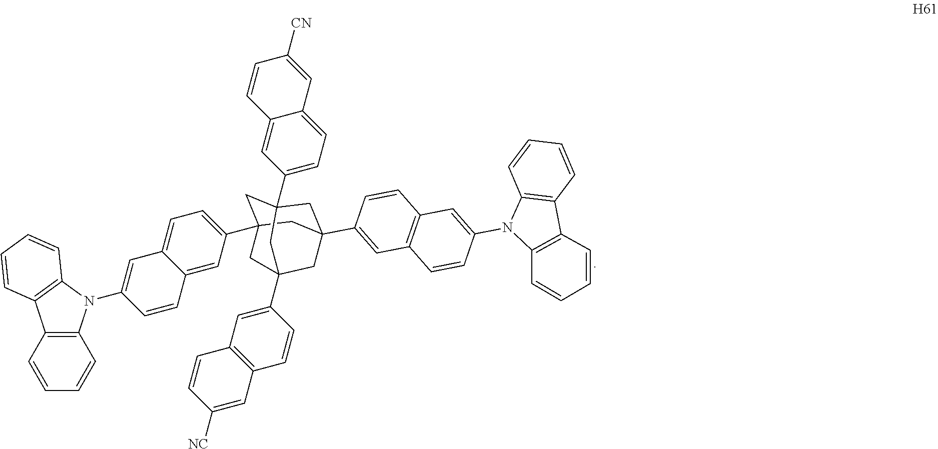 [SMILES: N#Cc1ccc2cc(C34CC5(c6ccc7cc(C#N)ccc7c6)CC(c6ccc7cc(-n8c9ccccc9c9ccccc98)ccc7c6)(C3)CC(c3ccc6cc(-n7c8ccccc8c8ccccc87)ccc6c3)(C4)C5)ccc2c1]

The compound according to the present disclosure is suitable for use as a host material of a light-emitting layer of an OLED.

The present disclosure also provides a display panel. The display panel includes an organic light-emitting device. The organic light-emitting device includes an anode, a cathode arranged opposite to the anode, and a light-emitting layer disposed between the anode and the cathode. The light-emitting layer includes a host material and a guest material. The host material of the light-emitting layer is one or more of the compounds according to the present disclosure.

According to an embodiment of the display panel of the present disclosure, the light-emitting layer is a blue light-emitting layer, and the host material is a host material of the blue light-emitting layer.

According to an embodiment of the display panel of the present disclosure, the host material has a higher singlet energy level S1 than the guest material, and a difference between the singlet energy level S1 of the host material and the singlet energy level S1 of the guest material is less than 0.8 eV; and the host material has a higher triplet energy level T1 than the guest material, and a difference between the triplet energy level T1 of the host material and the triplet energy level T1 of the guest material is less than 0.4 eV.

According to an embodiment of the display panel of the present disclosure, the organic light-emitting device further includes one or more layers of a hole injection layer, a hole transmission layer, an electron blocking layer, a hole blocking layer, an electron transmission layer, or an electron injection layer.

In the display panel provided by the present disclosure, the anode of the organic light-emitting device can be made of metal such as copper, gold, silver, iron, chromium, nickel, manganese, palladium, platinum, or alloys thereof. The anode can also be made of metal oxides such as indium oxide, zinc oxide, indium tin oxide (ITO), indium zinc oxide (IZO), or the like. The anode can also be made of a conductive polymer such as polyaniline, polypyrrole, poly(3-methylthiophene), or the like. In addition to the anode materials mentioned above, the anode can also be made of any suitable material known in the related art, or combinations thereof, as long as the material is conductive to hole injection.

In the display panel provided by the present disclosure, the cathode of the organic light-emitting device can be made of metal such as aluminum, magnesium, silver, indium, tin, titanium, or alloys thereof. The cathode also can be made of multiple-layered metal material, such as LiF/Al, LiO₂/Al, BaF₂/Al, or the like. In addition to the cathode materials listed above, the cathode also can be made of any suitable material known in the related art, or combinations thereof, as long as the material of the cathode is conductive to hole injection.

The organic light-emitting device according to the present disclosure can be manufactured according to methods well known in the art, which will not be elaborated herein. In the present disclosure, the organic light-emitting device can be manufactured by the following steps: forming an anode on a transparent or opaque smooth substrate; forming an organic thin layer on the anode; and further forming a cathode on the organic thin layer. The organic thin layer can be formed with a known method such as vapor deposition, sputtering, spin coating, dipping, ion plating, and the like.

The present disclosure also provides methods for preparing several exemplary compounds, as described in exemplary Examples 1-4 below.

### Example 1

### Synthesis of Compound H14

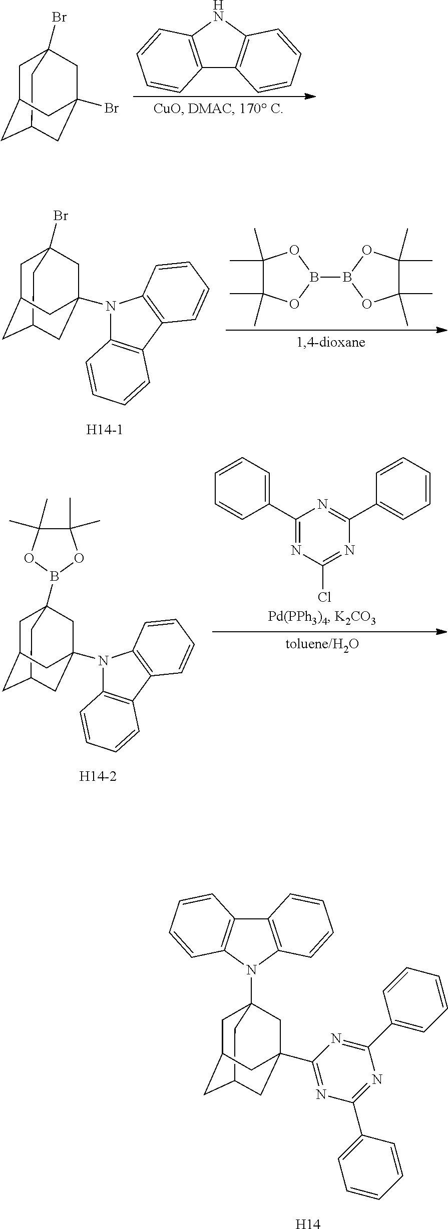

1,3-dibromoadamantane (15 mmol), cuprous oxide (40 mmol), and DMAC (20 ml) were refluxed in a 250 ml round-bottom flask under argon atmosphere for 48 h. The obtained intermediate was cooled to room temperature, added with water, and then filtered through a pad of celite. The filtrate was extracted with dichloromethane, then an organic phase was washed with water and dried over anhydrous magnesium sulfate. After filtering and evaporating the organic phase, the raw product was purified by column chromatography on silica gel to obtain an intermediate H14-1.

The intermediate H14-1 (15 mmol), potassium acetate (40 mmol), dried 1,4-dioxane (60 ml), Pd(PPh₃)₂Cl₂ (0.4 mmol) and pintanol diborate (25 mmol) were mixed in a 250 ml round-bottom flask, and the mixture was stirred under nitrogen atmosphere at 90° C. for 48 h. The obtained intermediate was cooled to room temperature, added with water, and then filtered through a pad of celite. The filtrate was extracted with dichloromethane, and then an organic phase was washed with water and dried over anhydrous magnesium sulfate. After filtering and evaporating the organic phase, the raw product was purified by column chromatography on silica gel to obtain an intermediate H14-2.

H03-2 (10 mmol), 2-chloro-4,6-diphenyl-1,3,5-triazine (12 mmol) and Pd(PPh₃)₄ (0.3 mmol) were added to a mixture of toluene (30 ml)/ethanol (20 ml) and an aqueous solution (10 ml) of potassium carbonate (12 mmol) in a 250 ml round-bottom flask, refluxed to react under nitrogen atmosphere for 12 h. The obtained mixture was cooled to room temperature, added with water, and then filtered through a pad of celite. The filtrate was extracted with dichloromethane, then washed with water and dried over anhydrous magnesium sulfate. After filtering and evaporating, the raw product was purified by column chromatography on silica gel to obtain an intermediate H14.

Elemental analysis of the Compound H14 (C₃₇H₄₆N₄): theoretical: C, 81.32; H, 8.42; N, 10.26; found: C, 81.32; H, 8.42; N, 10.26. MALDI-TOF MS: m/z calcd: 546.37, found: 546.38.

### Example 2

### Synthesis of Compound H23

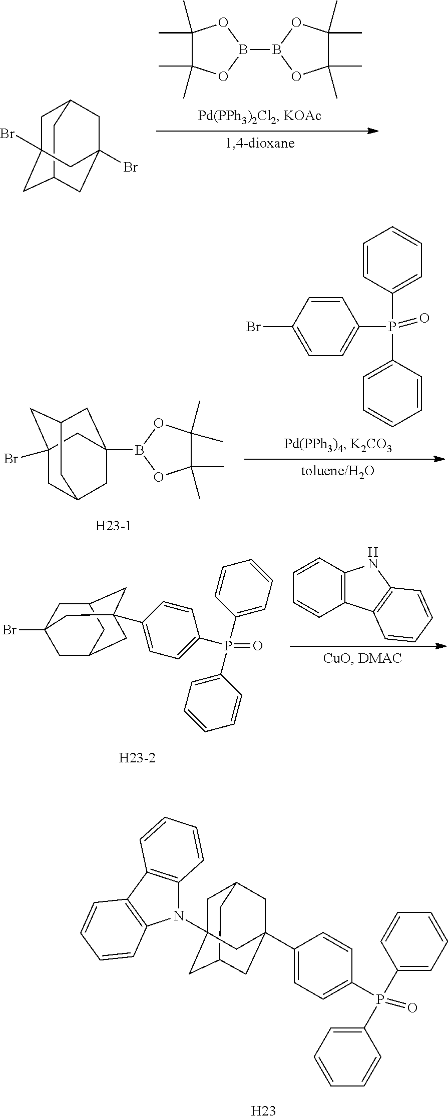

1,5-dibromoadamantane (15 mmol), potassium acetate (40 mmol), dried 1,4-dioxane (60 ml), Pd(PPh₃)₂Cl₂ (0.4 mmol) and pintanol diborate (25 mmol) were mixed in a 250 ml round-bottom flask, and the mixture was stirred under nitrogen atmosphere at 90° C. for 48 h. The obtained intermediate was cooled to room temperature, added with water, and then filtered through a pad of celite. The filtrate was extracted with dichloromethane, and then an organic phase was washed with water and dried over anhydrous magnesium sulfate. After filtering and evaporating the organic phase, the raw product was purified by column chromatography on silica gel to obtain an intermediate H023-2.

In a 250 ml round-bottom flask, H023-2 (10 mmol), (4-bromophenyl)diphenylphosphine oxide (12 mmol) and Pd(PPh₃)₄ (0.3 mmol) were added to a mixture of toluene (30 ml)/ethanol (20 ml) and an aqueous solution (10 ml) of potassium carbonate (12 mmol), refluxed to react under nitrogen atmosphere for 12 h. The obtained mixture was cooled to room temperature, added with water, and then filtered through a pad of celite. The filtrate was extracted with dichloromethane, then an organic phase was washed with water and dried over anhydrous magnesium sulfate. After filtering and evaporating the organic phase, the raw product was purified by column chromatography on silica gel to obtain an intermediate H023-3.

2,2-bis(4-iodo-phenyl)-adamantane (15 mmol), cuprous oxide (40 mmol), DMAC (20 ml), 9-hydrocarbazole were refluxed in a 250 ml round-bottom flask in argon atmosphere for 48 h. The obtained mixture was cooled to room temperature, added with water, and then filtered through a pad of celite. The filtrate was extracted with dichloromethane, then an organic phase was washed with water and dried over anhydrous magnesium sulfate. After filtering and evaporating the organic phase, the raw product was purified by column chromatography on silica gel to obtain a final product H023.

Elemental analysis of the Compound H023 (C₄₀H₃₆NOP): theoretical: C, 83.19; H, 6.24; N, 2.43; O, 2.77; P, 5.3; found: C, 83.19; H, 6.24; N, 2.43; O, 2.77; P, 5.37. MALDI-TOF MS: m/z calcd: 577.25, found: 577.24.

### Example 3

### Synthesis of Compound H29

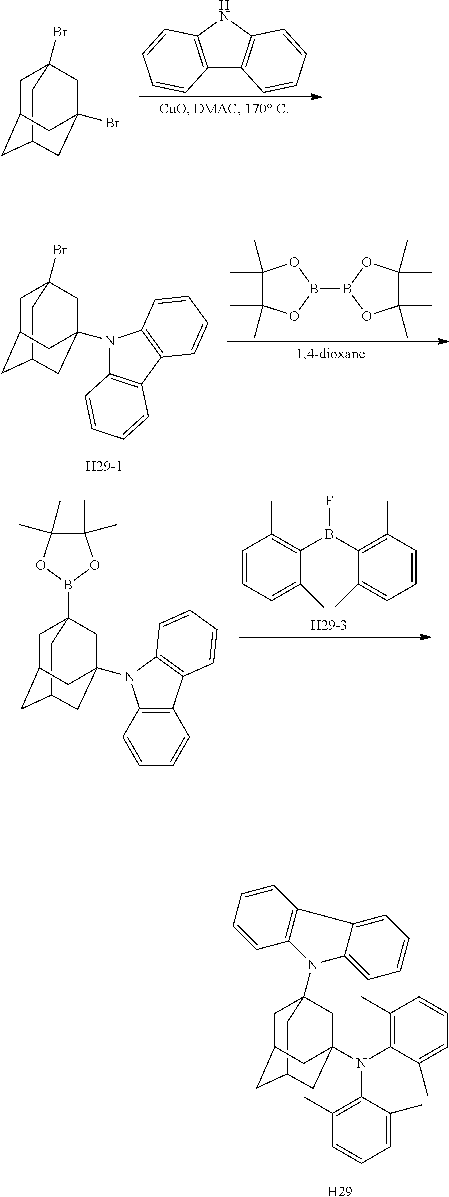

1,3-dibromoadamantane (15 mmol), cuprous oxide (40 mmol), and DMAC (20 ml) were refluxed in a 250 ml round-bottom flask under argon atmosphere for 48 h. The obtained intermediate was cooled to room temperature, added with water, and then filtered through a pad of celite. The filtrate was extracted with dichloromethane, then an organic phase was washed with water and dried over anhydrous magnesium sulfate. After filtering and evaporating the organic phase, the raw product was purified by column chromatography on silica gel to obtain an intermediate H29-1.

The intermediate H29-1 (15 mmol) and potassium acetate (40 mmol), dried 1,4-dioxane (60 ml), Pd(PPh₃)₂Cl₂ (0.4 mmol) and pintanol diborate (25 mmol) were mixed in a 250 ml round-bottom flask, stirring under nitrogen atmosphere at 90° C. for 48 h. The obtained intermediate was cooled to room temperature, added with water, and then filtered through a pad of celite. The filtrate was extracted with dichloromethane, and then an organic phase was washed with water and dried over anhydrous magnesium sulfate. After filtering and evaporating the organic phase, the raw product was purified by column chromatography on silica gel to obtain an intermediate H29-2.

H29-2 (10 mmol) was weighed and added into a 100 mL flask having two necks. Degassing and nitrogen displacement were repeated three times while stiring. 40 mL of dried ether was added to dissolve S22, and n-BuLi solution (10.5 mmol) was added dropwise at −78° C. After stirring for 15 min, the mixture was slowly warmed to room temperature and stirred for 1 h. The temperature was lowered to −78° C. again, a solution of H29-3 in ether (10.2 mmol, 25 mL) was added dropwise. After stirring for 30 min, the mixture was slowly warmed to room temperature overnight, and evaporated under reduced pressure to remove the volatile solvent. The raw product was washed with methanol (5×10 mL), and finally refined by column chromatography to obtain Compound H29.

Elemental analysis of the Compound H29 (C₃₈H₄₀BN): theoretical: C, 87.52; H, 7.68; B, 2.11; N, 2.69; found: C, 87.52; H, 1.92; B, 7.87; N, 2.69. MALDI-TOF MS: m/z calcd: 521.33; found: 521.34.

### Example 4

### Synthesis of Compound H55

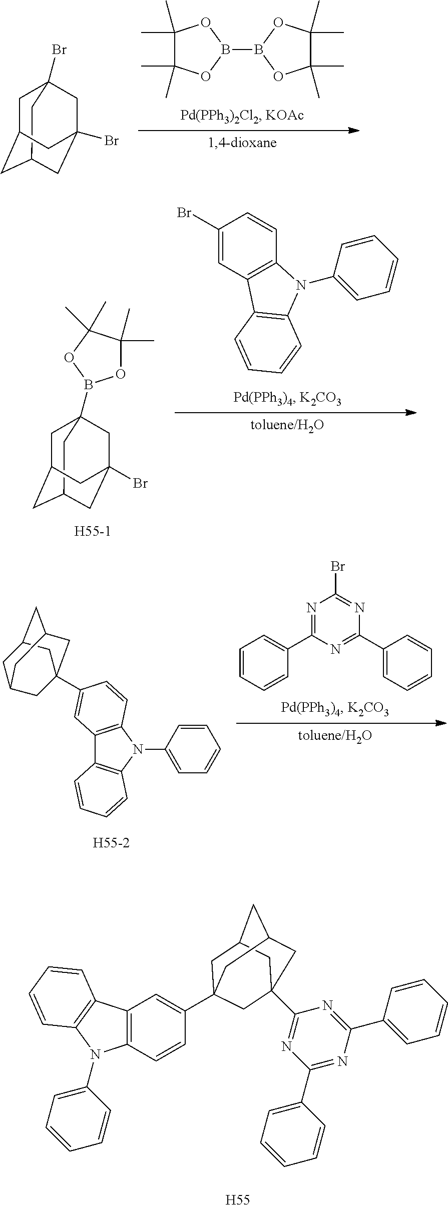

1,3-dibromoadamantane (15 mmol), potassium acetate (40 mmol), dried 1,4-dioxane (60 ml), Pd(PPh₃)₂Cl₂ (0.4 mmol) and pintanol diborate (25 mmol) were mixed in a 250 ml round-bottom flask, stirring under nitrogen atmosphere at 90° C. for 48 h. The obtained intermediate was cooled to room temperature, added with water, and then filtered through a pad of celite. The filtrate was extracted with dichloromethane, and then an organic phase was washed with water and dried over anhydrous magnesium sulfate. After filtering and evaporating the organic phase, the raw product was purified by column chromatography on silica gel to obtain an intermediate H55-1.

In a 250 ml round-bottom flask, H55-1 (10 mmol), 3-bromo-9-phenyl-9H-carbazole (12 mmol) and Pd(PPh₃)₄ (0.3 mmol) were added to a mixture of toluene (30 ml)/ethanol (20 ml) and an aqueous solution (10 ml) of potassium carbonate (12 mmol), refluxed to react under nitrogen atmosphere for 12 h. The obtained mixture was cooled to room temperature, added with water, and then filtered through a pad of celite. The filtrate was extracted with dichloromethane, then an organic phase was washed with water and dried over anhydrous magnesium sulfate. After filtering and evaporating the organic phase, the raw product was purified by column chromatography on silica gel to obtain an intermediate H55-2.

In a 250 ml round-bottom flask, H55-2 (10 mmol), 4-bromo-2,6-diphenyltriazine (12 mmol) and Pd(PPh₃)₄ (0.3 mmol) were added to a mixture of toluene (30 ml)/ethanol (20 ml) and an aqueous solution (10 ml) of potassium carbonate (12 mmol), refluxed to react under nitrogen atmosphere for 12 h. The obtained mixture was cooled to room temperature, added with water, and then filtered through a pad of celite. The filtrate was extracted with dichloromethane, then an organic phase was washed with water and dried over anhydrous magnesium sulfate. After filtering and evaporating the organic phase, the raw product was purified by column chromatography on silica gel to obtain a final product H55.

Elemental analysis of the Compound H055 (C₄₃H₃₆N₄): theoretical: C, 84.87; H, 5.92; N, 9.21; found: C, 84.87; H, 5.92; N, 9.21. MALDI-TOF MS: m/z calc.: 608.29; found: 608.28.

Parameters of the compounds H14, H23, H29 and H55 were tested and the test results are shown in Table 1.

TABLE 1
Energy levels of exemplary compounds

| Compound | HOMO (eV) | LUMO (eV) | Eg (eV) | E_{T} (eV) |
|---|---|---|---|---|
| H14 | −5.276 | −1.952 | 3.324 | 3.0217 |
| H23 | −5.675 | −1.565 | 4.110 | 3.1821 |
| H29 | −5.962 | −3.013 | 2.949 | 3.0726 |
| H55 | −5.548 | −2.439 | 3.109 | 3.0282 |

As can be seen from Table 1, as the host material, H14, H23, H29 and H55 exhibit suitable HOMO and LUMO energy levels and high triplet ET (>3.0282 eV), in which a material having ET>2.2 eV is suitable as a host material in a red light-emitting device, a material having ET>2.5 eV is suitable as a host material in a green light-emitting device, and a material having ET>2.2 eV is suitable as a host material in a blue light-emitting device. In this way, the energy transfer between the host material and the guest material can be achieved without the risk of charge return.

### Device Example 1

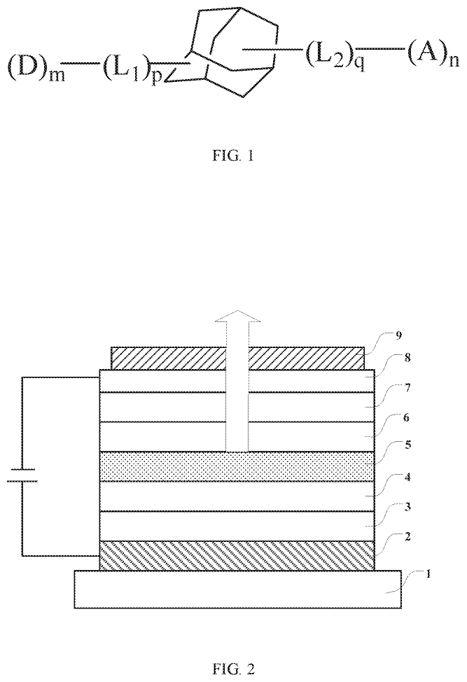

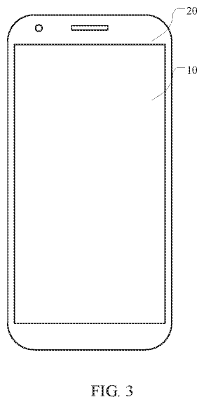

The present example provides an organic light-emitting device of a display panel. As shown in FIG. 2, the organic light-emitting device includes: a glass substrate 1, an ITO anode 2, a first hole transmission layer 3, a second hole transmission layer 4, a light-emitting layer 5, a first electron transmission layer 6, a second electron transmission layer 7, a cathode 8 (magnesium silver electrode, a mass ratio of magnesium to silver is 9:1) and a capping layer (CPL) 9. The ITO anode 2 has a thickness of 15 nm. The first hole transmission layer 3 has a thickness of 10 nm. The second hole transmission layer 4 has a thickness of 95 nm. The light-emitting layer 5 has a thickness of 30 nm. The first electron transmission layer 6 has a thickness of 30 nm. The second electron transmission layer 7 has a thickness of 5 nm. The magnesium silver electrode 8 has a thickness of 15 nm. The capping layer (CPL) 9 has a thickness of 100 nm.

The organic light-emitting device according to the present disclosure are prepared by the following steps.

1) A glass substrate 1 was cut into a size of 50 mm×50 mm×0.7 mm, subjected to ultrasonic treatments in isopropyl alcohol and in deionized water for 30 minutes, respectively, and then exposed to ozone for about 10 minutes for cleaning. The obtained glass substrate with an ITO anode 2 was mounted on a vacuum deposition apparatus.

2) A hole injection layer material HAT-CN was evaporated on the ITO anode 2 by vacuum evaporation to obtain a layer having a thickness of 10 nm and used as the first hole transmission layer 3.

3) The material TAPC of the second hole transmission layer 4 was evaporated by vacuum evaporation on the first hole transmission layer 3 to obtain a layer having a thickness of 95 nm and used as the second hole transmission layer 4.

4) The light-emitting layer 5 was co-deposited on the hole transmission layer 4, where Compound H014 was used as a host material, Ir(ppy)₃ was used as a doping material, and a mass ratio of Compound H014 to Ir(ppy)₃ was 19:1. The light-emitting layer 5 has a thickness of 30 nm.

5) The material BPen of the first electron transmission layer 6 was evaporated on the light-emitting layer 5 so as to obtain the first electron transmission layer 6 having a thickness of 30 nm.

6) The material Alq3 of the second electron transmission layer 7 was evaporated by vacuum evaporation on the first electron transmission layer 6 to obtain the second electron transmission layer 7 having a thickness of 5 nm.

7) The magnesium silver electrode was evaporated by vacuum evaporation on the second electron transmission layer 7 to manufacture the cathode 8 having a thickness of 15 nm, in which the mass ratio of Mg to Ag is 9:1.

8) The hole material CBP having a high refractive index was evaporated by vacuum evaporation on the cathode 8 to a thickness of 100 nm and used as a cathode covering layer (capping layer or CPL) 9.

The compounds and structures involved in this example are shown as follows.

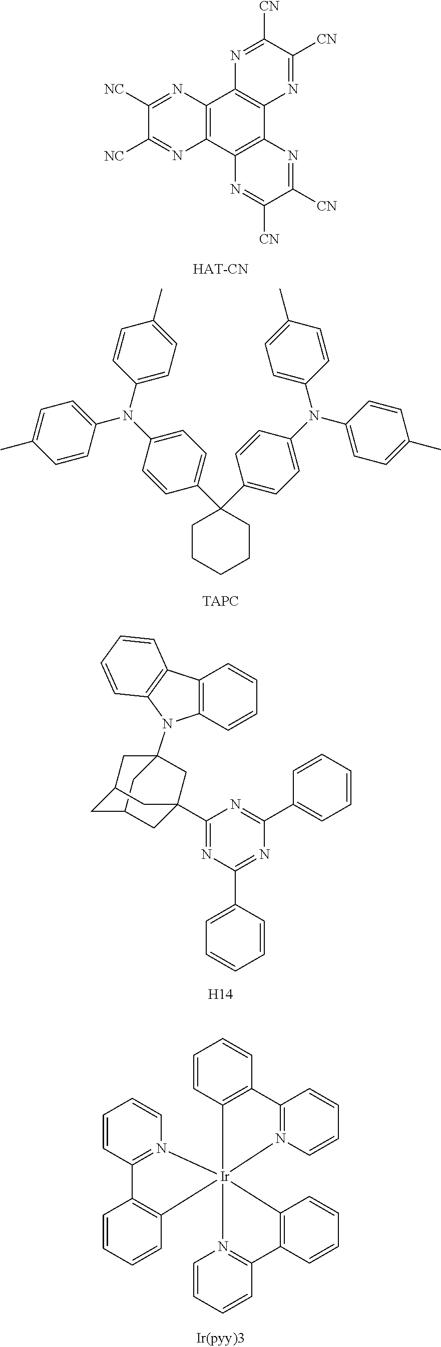

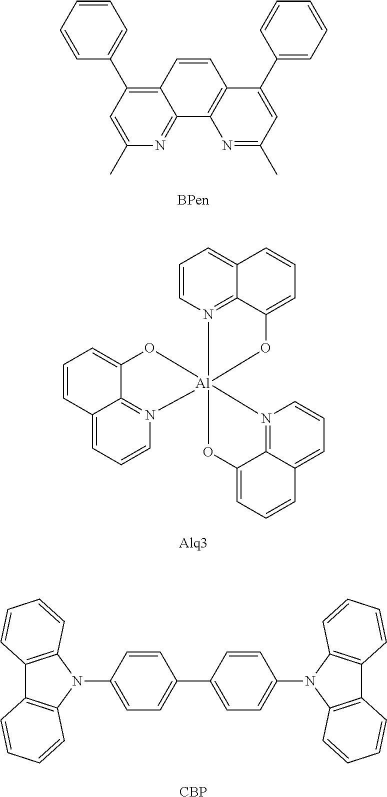

### Device Example 2

Device Example 2 differs from Device Example 1 in that the host material is H23. The other materials of other layers are all the same.

### Device Example 3

Device Example 3 differs from Device Example 1 in that the host material is H29. The other materials of other layers are all the same.

### Device Example 4

Device Example 4 differs from Device Example 1 in that the host material is H55. The other materials of other layers are all the same.

### Comparative Device Example 1

Comparative Device Example 1 differs from Device Example 1 in that the host material is CzTRZ. The other materials of other layers are all the same.

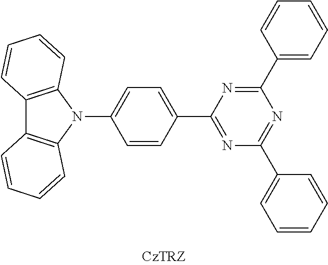 [SMILES: c1ccc(-c2nc(-c3ccccc3)nc(-c3ccc(-n4c5ccccc5c5ccccc54)cc3)n2)cc1]

TABLE 2
characterization of light-emitting device performance

| No. | Host material | Drive voltage (V) | EQE | CE (cd/A) |
|---|---|---|---|---|
| Example 1 | H14 | 3.65 | 31.2% | 128.9 |
| Example 2 | H23 | 3.12 | 28.3% | 117.7 |
| Example 3 | H029 | 3.38 | 30.7% | 126.1 |
| Example 4 | H055 | 3.76 | 35.6% | 134.8 |
| Comparative | CzTRZ | 4.10 | 24.2 | 103.2 |
| Example 1 | | | | |

As can be seen from the above Table 2, the light-emitting device using the compound of the present disclosure as a host material has a lower driving voltage, so that the power consumption of the device can be effectively reduced. Compared with the comparative device 1, when the light-emitting device adopts the compound of the present disclosure as a host material, the light-emitting efficiency is higher, the luminance of the device can be effectively improved, and the service life of the device is also prolonged.

The present disclosure also provides a display apparatus including the organic light-emitting display panel as described above. In the present disclosure, the organic light-emitting device can be an OLED, which may be used in an organic light-emitting display apparatus. The organic light-emitting apparatus can be a mobile phone display screen, a computer display screen, a liquid crystal television display screen, a smart watch display screen, or a smart car display panel, VR or AR helmet display screen, or display screens of various smart devices. FIG. 3 is a schematic diagram of a display apparatus according to an embodiment of the present disclosure. In FIG. 3, a mobile phone display panel is denoted with reference number 10, a display apparatus is denoted with reference number 20.

The above embodiments of the present disclosure are several preferred embodiments, but not intended to limit the scope of the claims. Any change and modification can be made by those skilled in the art without departing from the scope of the present application, and the protection scope is defined by the claims.

What is claimed is:

1. A compound having a chemical structure according to Formula (I): 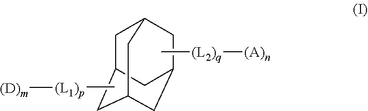
wherein
D is an electron donor;
A is an electron acceptor;
m is a number of D,
n is a number of A;
m and n are each an integer independently selected from 1, 2 or 3;
p is a number of L₁;
q is a number of L₂;
p and q are each an integer independently selected from 0, 1 or 2;
L₁ and L₂ are each independently selected from the group consisting of a single bond, a substituted or unsubstituted C1-C20 alkylene, a substituted or unsubstituted C3-C20 cycloalkylene, a substituted or unsubstituted C3-C20 heterocyclic alkylene, a substituted or unsubstituted C6-C40 arylene, a substituted or unsubstituted C4-C40 heteroarylene, a substituted or unsubstituted C10-C60 fused arylene, a substituted or unsubstituted C10-C60 fused heteroarylene, and combinations thereof;
D is selected from the group consisting of a substituted or unsubstituted C1-C20 alkyl, a substituted or unsubstituted C3-C20 cycloalkyl, a substituted or unsubstituted C1-C20 alkoxy, a substituted or unsubstituted C3-C20 heterocyclic group, a substituted or unsubstituted C6-C40 aryl, a substituted or unsubstituted C4-C40 heteroaryl, a substituted or unsubstituted C10-C60 fused aryl, a substituted or unsubstituted C10-C60 fused heteroaryl, a substituted or unsubstituted C12-C40 carbazolyl and its derivative groups, a substituted or unsubstituted C12-C40 diphenylamino and its derivative groups, a substituted or unsubstituted C18-C60 triphenylamino and its derivative groups, a substituted or unsubstituted C13-C40 acridinyl and its derivative groups, and combinations thereof; and
A is selected from the group consisting of a nitrogen-containing heterocyclic group, a cyano-containing group, a triarylboron-based group, a benzophenone-based group, a heteroaromatic ketone-based group, a sulfone-based group, a phosphoroso-containing groups, and combinations thereof.

2. The compound according to claim 1, wherein the compound has any one of the following chemical structures: 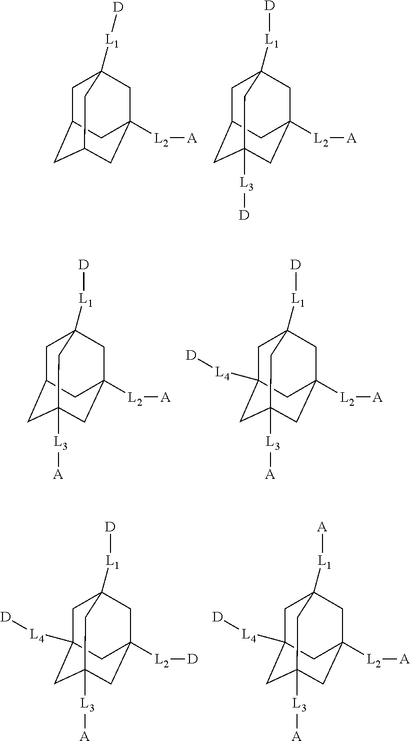
wherein L₃ and L₄ are each independently selected from the group consisting of a single bond, a substituted or unsubstituted C1-C20 alkylene, a substituted or unsubstituted C3-C20 cycloalkylene, a substituted or unsubstituted C3-C20 heterocyclic alkylene, a substituted or unsubstituted C6-C40 arylene, a substituted or unsubstituted C4-C40 heteroarylene, a substituted or unsubstituted C10-C60 fused arylene, a substituted or unsubstituted C10-C60 fused heteroarylene, and combinations thereof.

3. The compound according to claim 1, wherein D is according to any one of the following formulas: 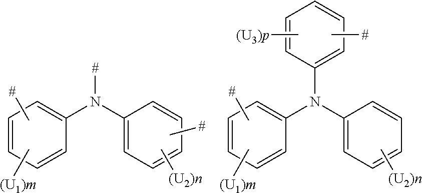
wherein m, n and p are each an integer independently selected from 0, 1, 2 or 3;
U₁, U₂, U₃ are each independently selected from the group consisting of a hydrogen atom, a substituted or unsubstituted C1-C30 alkyl, a substituted or unsubstituted silylene, a substituted or unsubstituted C3-C20 cycloalkyl, a substituted or unsubstituted C1-C30 alkoxy, a substituted or unsubstituted C6-C30 aryl, a substituted or unsubstituted C10-C30 fused aryl, and combinations thereof; and
# indicates a bonding position.

4. The compound according to claim 3, wherein D is according to any one of the following formulas: 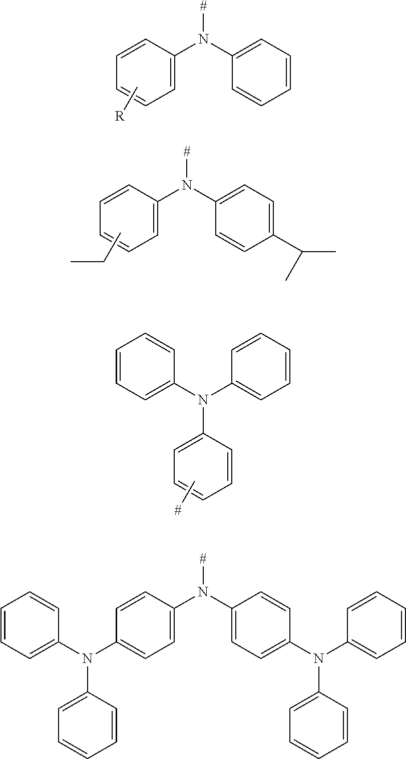
wherein R is selected from the group consisting of a hydrogen atom, a substituted or unsubstituted C1-C20 alkyl, a substituted or unsubstituted silylene group, a substituted or unsubstituted C3-C20 cycloalkyl, a substituted or unsubstituted C1-C20 alkoxy, a substituted or unsubstituted C3-C20 heterocyclic group, a substituted or unsubstituted C6-C40 aryl, a substituted or unsubstituted C10-C30 fused aryl, and a substituted or unsubstituted C4-C40 heteroaryl.

5. The compound according to claim 1, wherein D is according to any one of the following formulas: 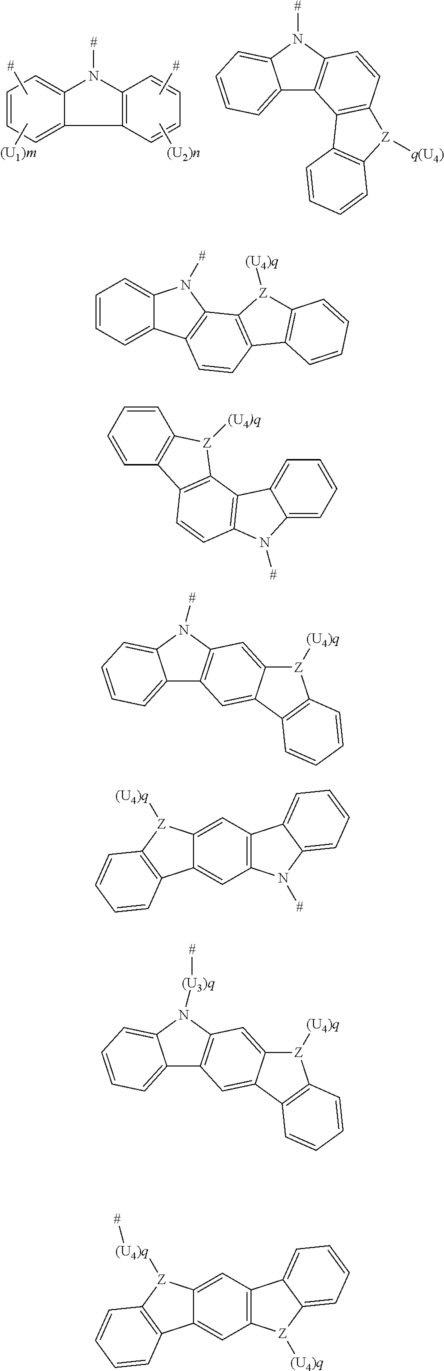
wherein
Z is selected from the group consisting of a carbon atom, a nitrogen atom, an oxygen atom, a sulfur atom, and a silicon atom;
m, n and q are each an integer independently selected from 0, 1, 2 or 3;
U₁, U₂, U₃ and U₄ are each independently selected from the group consisting of a hydrogen atom, a substituted or unsubstituted C1-C30 alkyl, a substituted or unsubstituted silylene, a substituted or unsubstituted C3-C20 cycloalkyl, a substituted or unsubstituted C1-C30 alkoxy, a substituted or unsubstituted C6-C30 aryl, a substituted or unsubstituted C10-C30 fused aryl, and combinations thereof;
when Z is an oxygen atom or a sulfur atom, q is 0; and
# indicates a bonding position.

6. The compound according to claim 5, wherein D is according to any one of the following formulas: 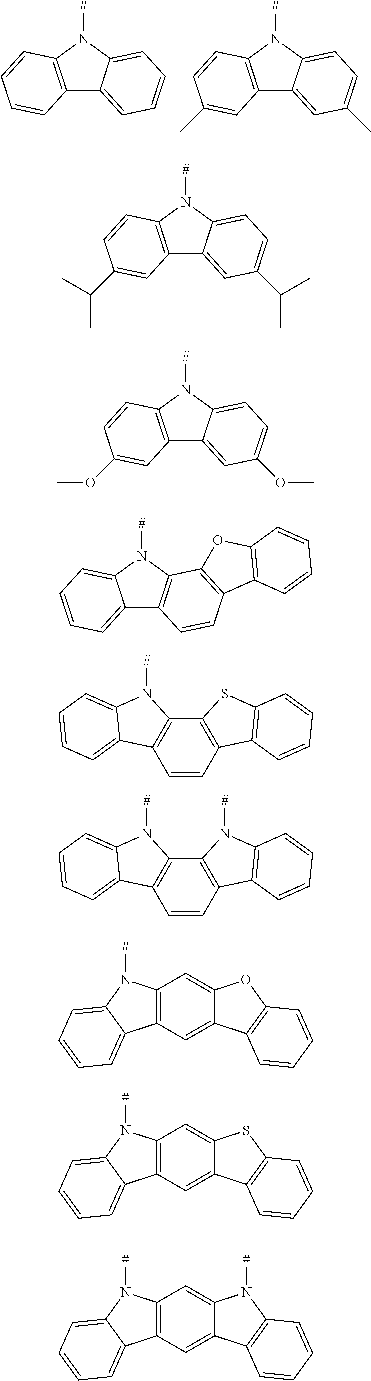 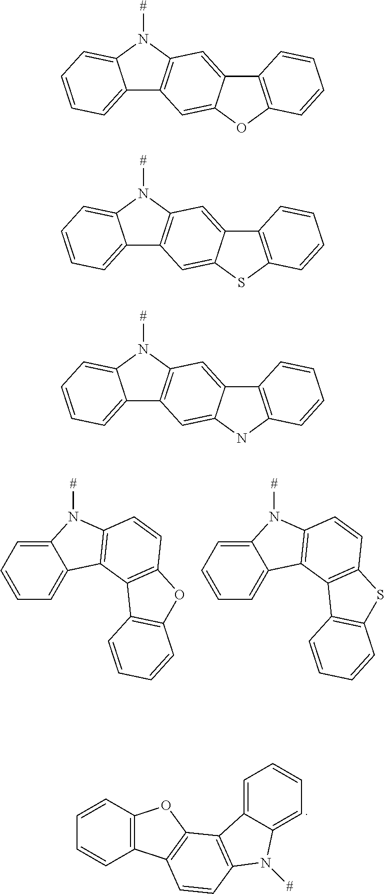
# indicates a bonding position.

7. The compound according to claim 1, wherein D is according to any one of the following formulas: 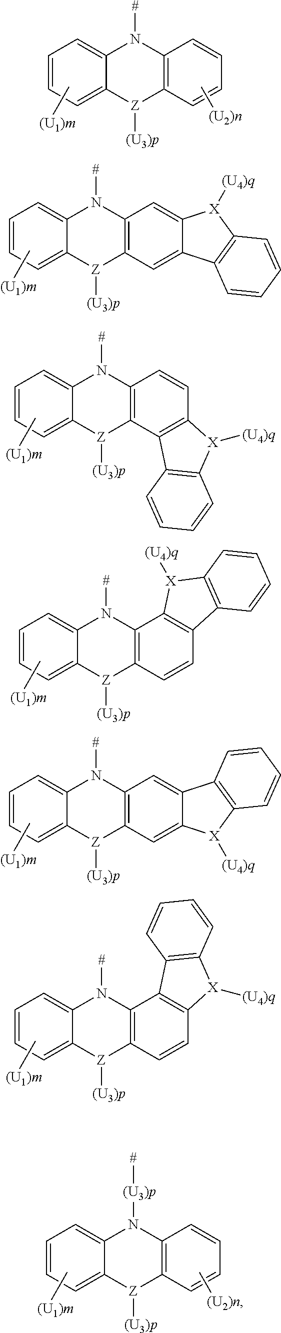
wherein
Z is selected from the group consisting of a carbon atom, a nitrogen atom, an oxygen atom, a sulfur atom and a silicon atom;
X is selected from the group consisting of a carbon atom, a nitrogen atom, an oxygen atom and a sulfur atom;
m, n, p and q are each an integer independently selected from 0, 1, 2 or 3;
U₁, U₂, U₃ and U₄ are each independently selected from the group consisting of a hydrogen atom, a substituted or unsubstituted C1-C30 alkyl, a substituted or unsubstituted silylene, a substituted or unsubstituted C3-C20 cycloalkyl, a substituted or unsubstituted C1-C30 alkoxy, a substituted or unsubstituted C6-C30 aryl, and a substituted or unsubstituted C10-C30 fused aryl, and combinations thereof;
when Z is an oxygen atom or a sulfur atom, p is 0;
when X is an oxygen atom or a sulfur atom, q is 0; and
# indicates a bonding position.

8. The compound according to claim 7, wherein D is according to any one of the following formulas: 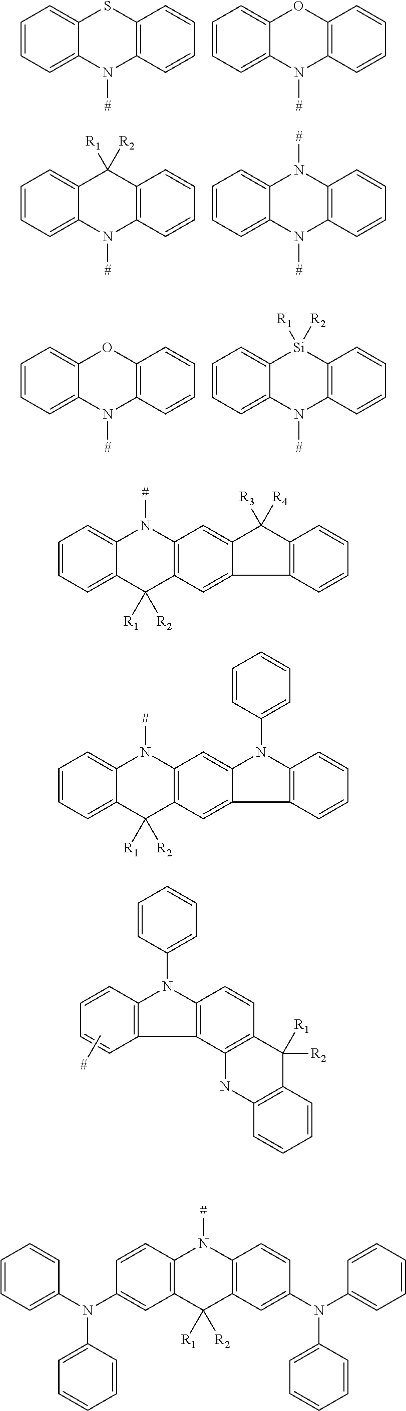
wherein R₁, R₂, R₃ and R₄ are each independently selected from the group consisting of a hydrogen atom, a substituted or unsubstituted C1-C20 alkyl, a substituted or unsubstituted C3-C20 cycloalkyl, a substituted or unsubstituted C1-C20 alkoxy, a substituted or unsubstituted C3-C20 heterocyclic group, a substituted or unsubstituted C6-C40 aryl, and a substituted or unsubstituted C4-C40 heteroaryl.

9. The compound according to claim 1, wherein A is according to any one of the following formulas: 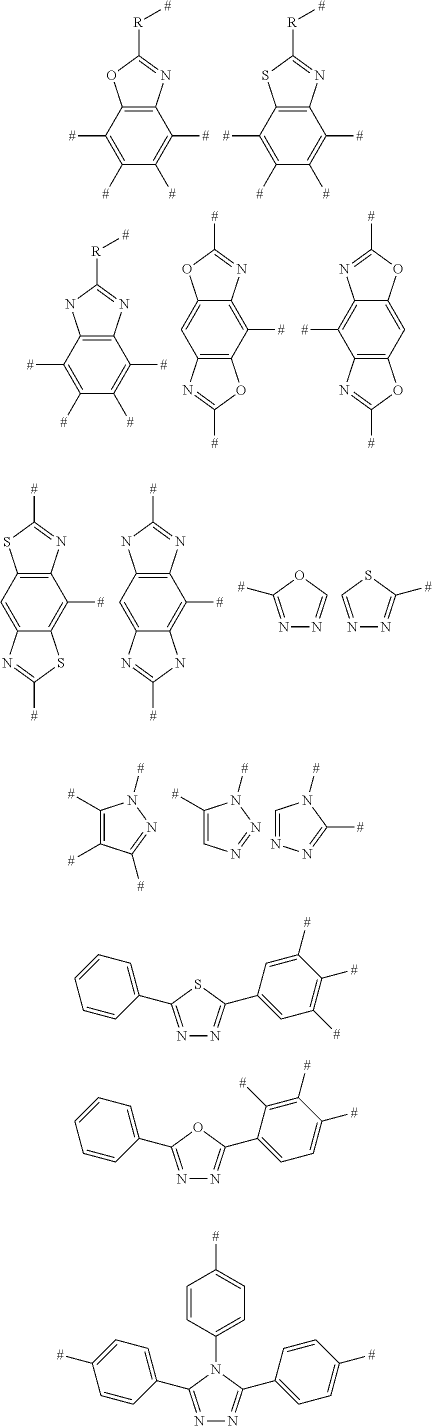 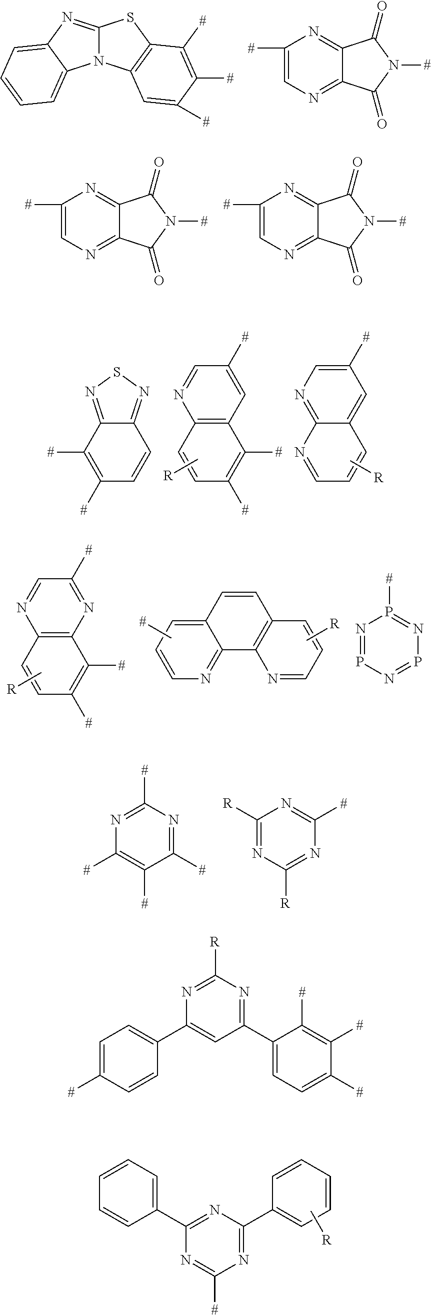 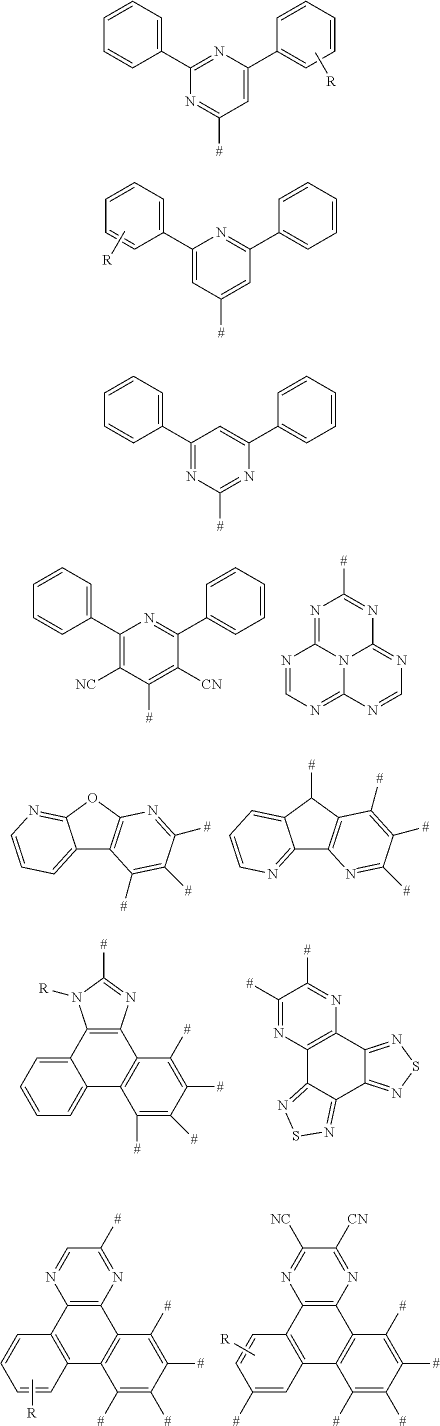 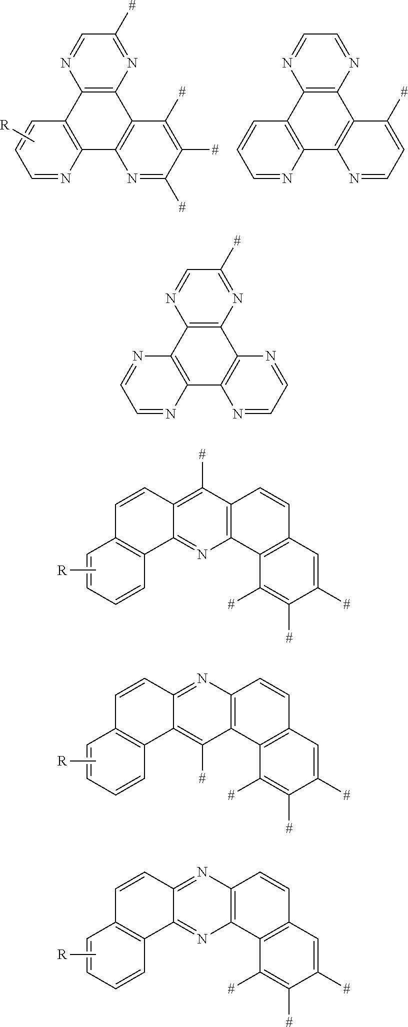
wherein
R is selected from the group consisting of a hydrogen atom, a C1-C20 alkyl, a C1-C20 alkoxy, a C4-C8 cycloalkyl, a C6-C40 aryl, and a C4-C40 heteroaryl; and
# indicates a bonding position.

10. The compound according to claim 1, wherein A is according to any one of the following formulas: 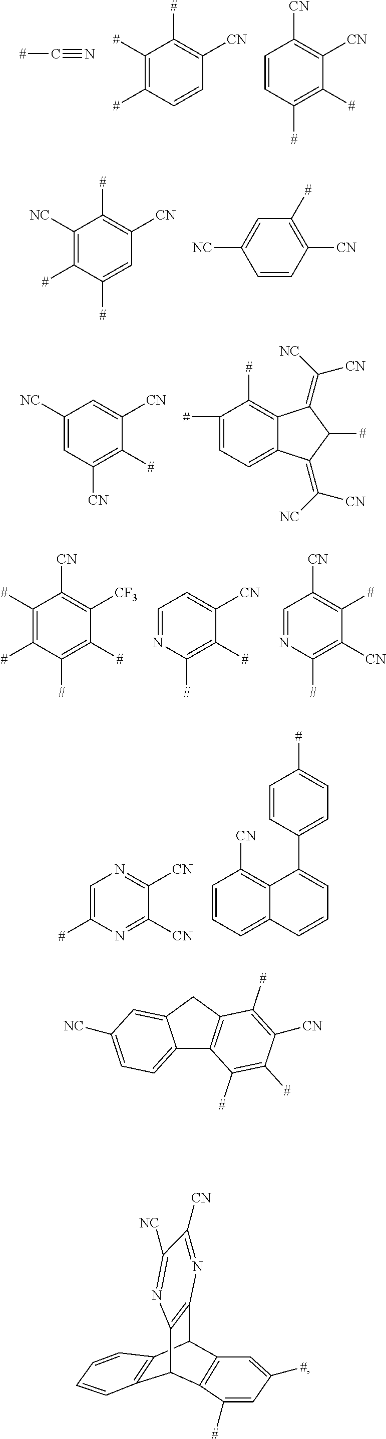
wherein # indicates a bonding position.

11. The compound according to claim 1, wherein A is according to any one of the following formulas: 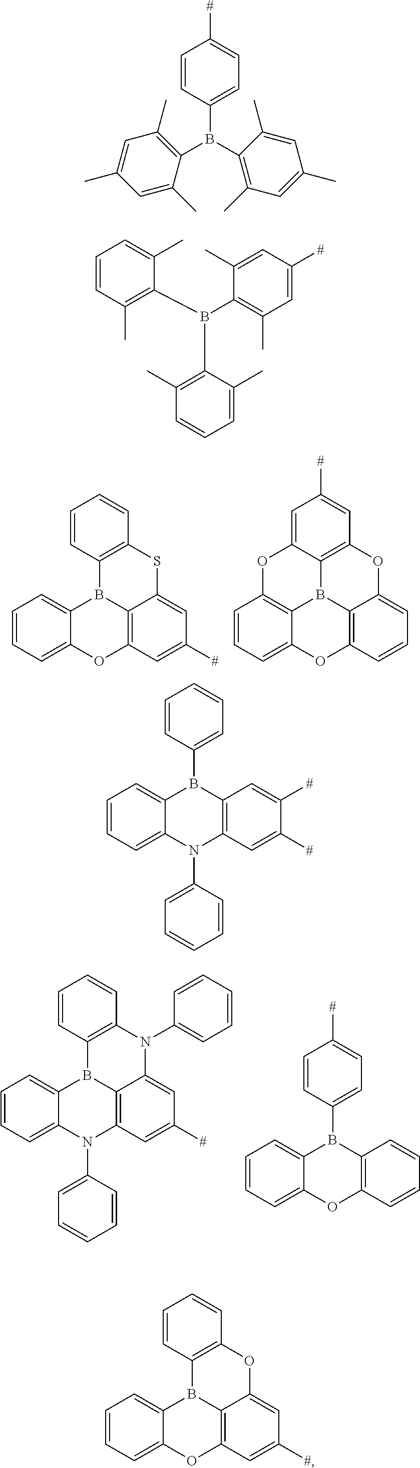
wherein # indicates a bonding position.

12. The compound according to claim 1, wherein A is according to any one of the following formulas: 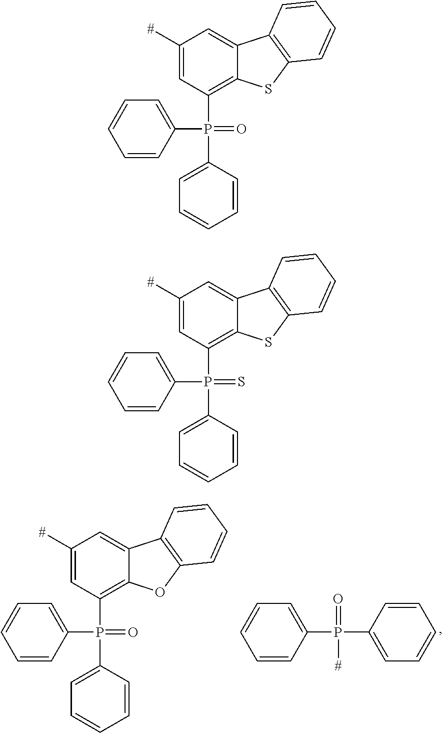
wherein # indicates a bonding position.

13. The compound according to claim 1, wherein L₁ and L₂ are each independently selected from any one of the following formulas: 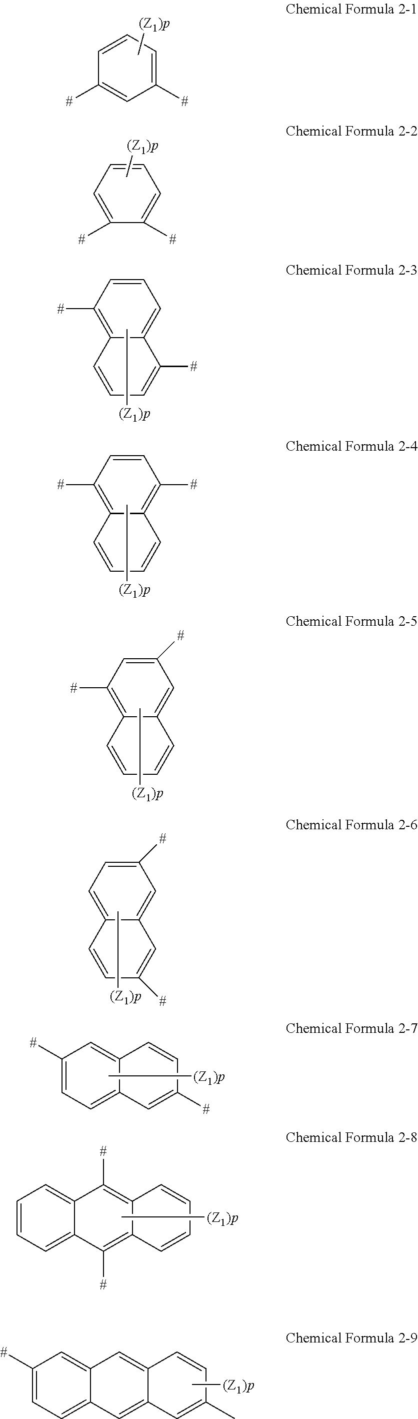 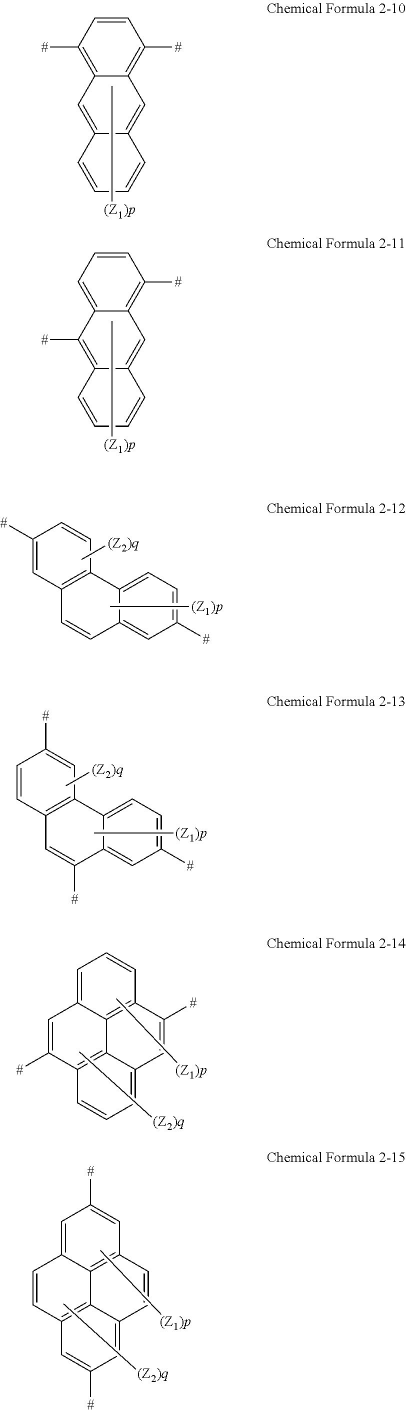 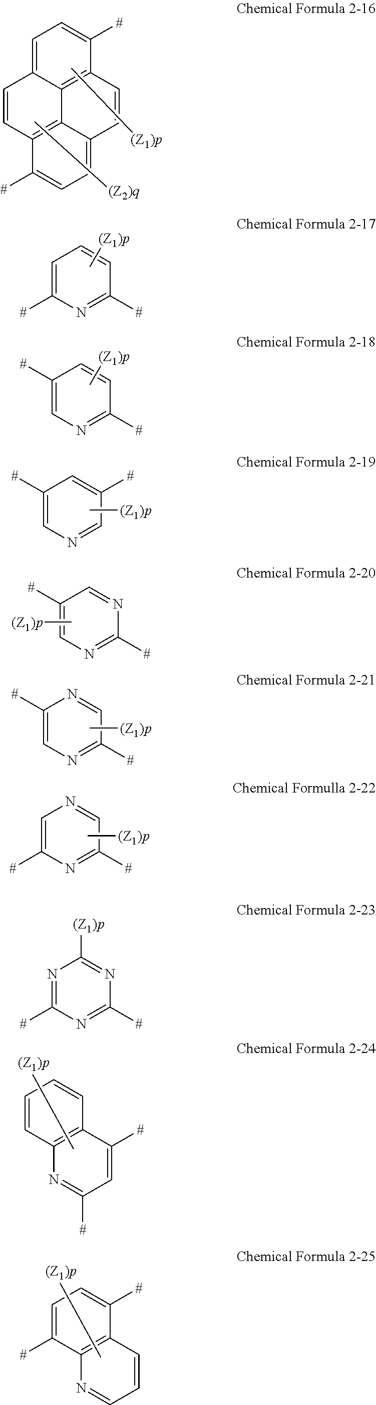 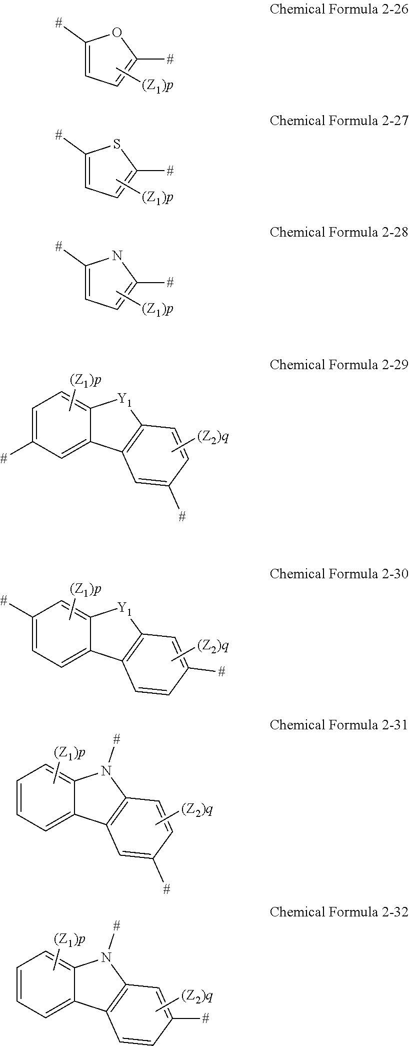
wherein
Z₁ and Z₂ are each independently selected from the group consisting of a hydrogen atom, a substituted or unsubstituted C6-C30 aryl, a substituted or unsubstituted C6-C30 fused aryl, and a substituted or unsubstituted C6-C30 fused heteroaryl;
p and q are each an integer greater than or equal to 0; and
# indicates a bonding position.

14. The compound according to claim 13, wherein L₁ and L₂ are each independently selected from any one of the following formulas: 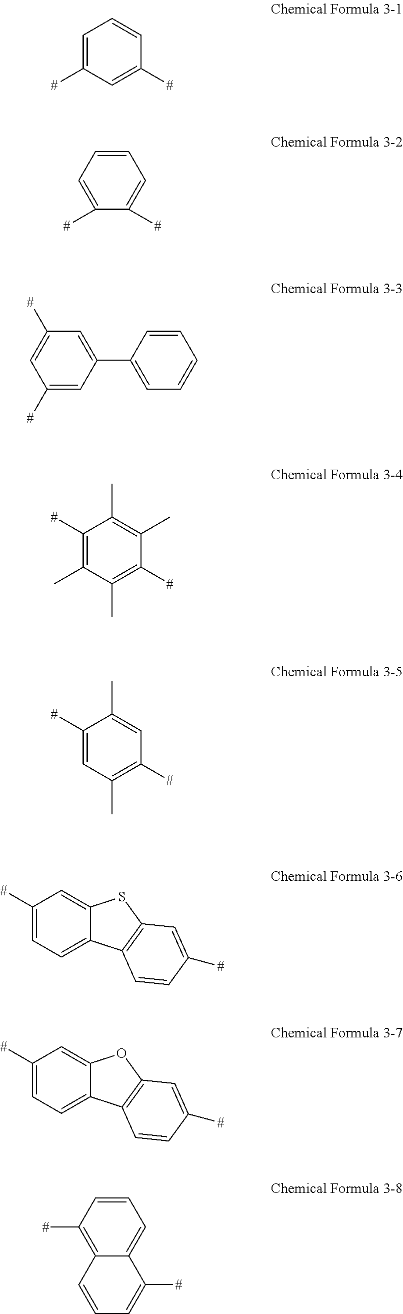 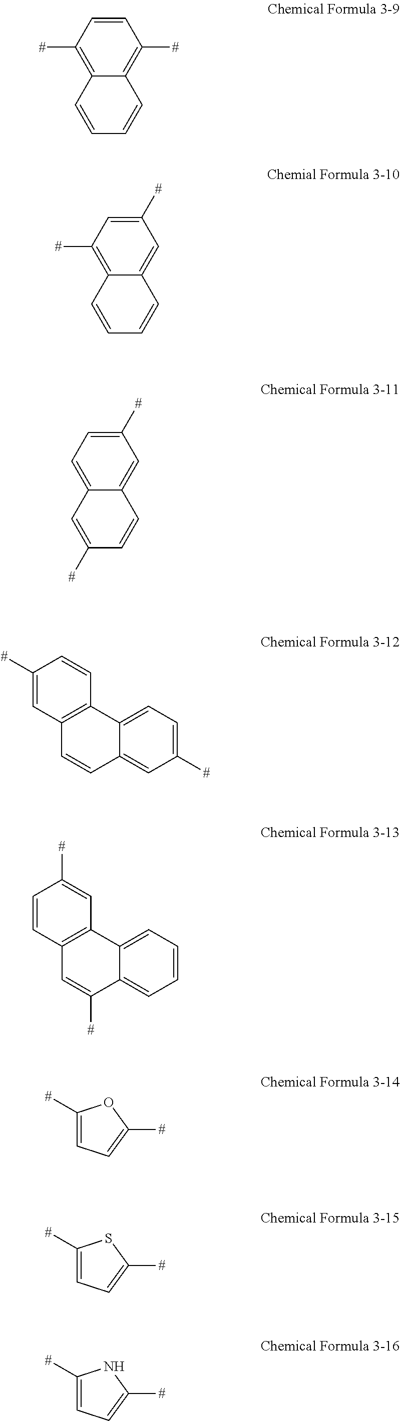 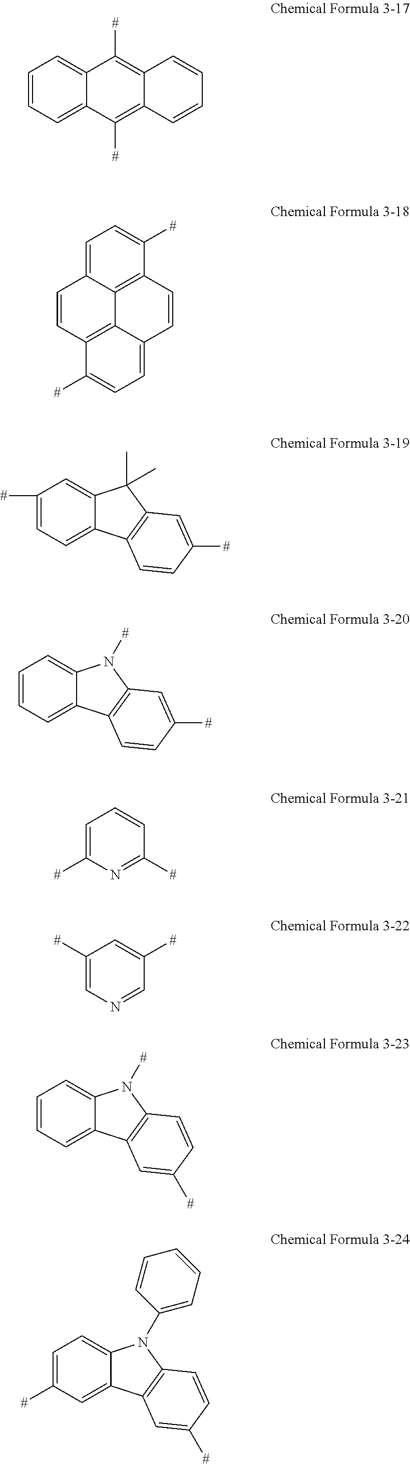
wherein # indicates a bonding position.

15. The compound according to claim 1, wherein the compound is selected from the group consisting of the following compounds:

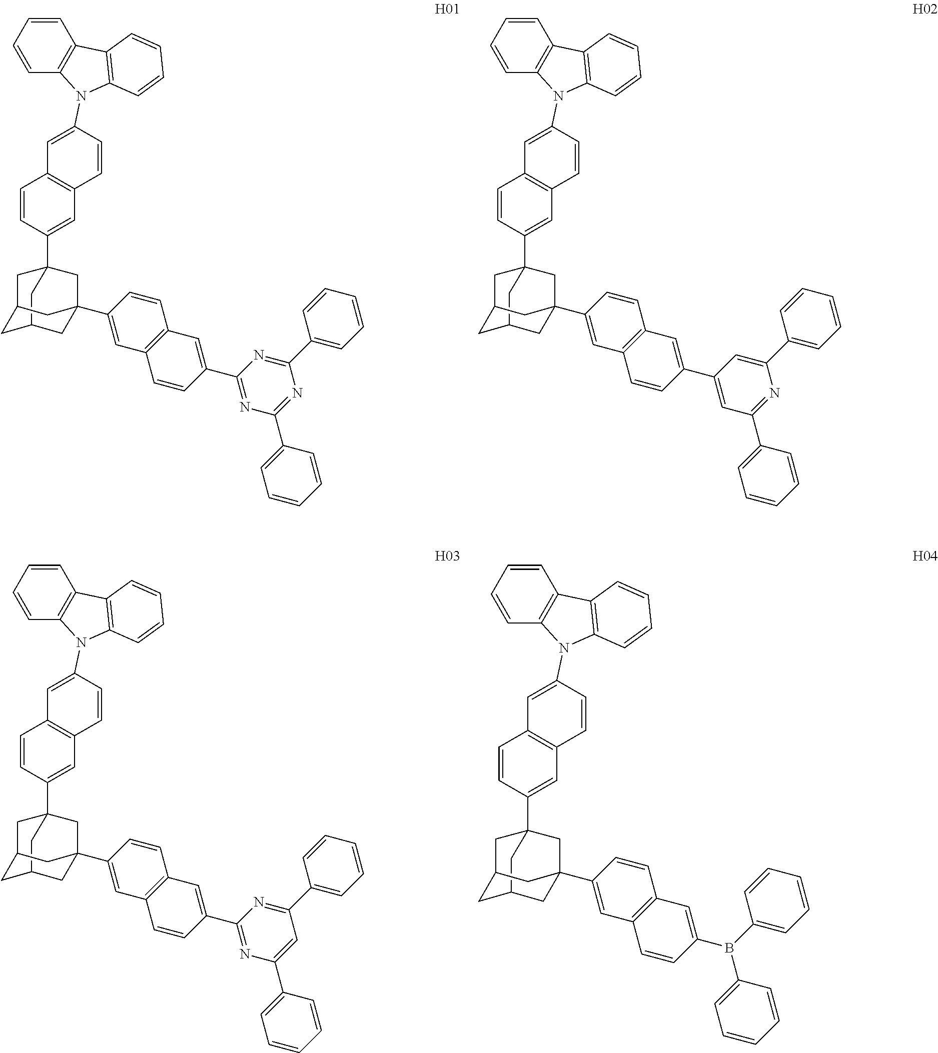 [SMILES: c1ccc(-c2nc(-c3ccccc3)nc(-c3ccc4cc(C56CC7CC(C5)CC(c5ccc8cc(-n9c%10ccccc%10c%10ccccc%109)ccc8c5)(C7)C6)ccc4c3)n2)cc1 ; c1ccc(-c2cc(-c3ccc4cc(C56CC7CC(C5)CC(c5ccc8cc(-n9c%10ccccc%10c%10ccccc%109)ccc8c5)(C7)C6)ccc4c3)cc(-c3ccccc3)n2)cc1 ; c1ccc(-c2cc(-c3ccccc3)nc(-c3ccc4cc(C56CC7CC(C5)CC(c5ccc8cc(-n9c%10ccccc%10c%10ccccc%109)ccc8c5)(C7)C6)ccc4c3)n2)cc1 ; c1ccc(B(c2ccccc2)c2ccc3cc(C45CC6CC(C4)CC(c4ccc7cc(-n8c9ccccc9c9ccccc98)ccc7c4)(C6)C5)ccc3c2)cc1]

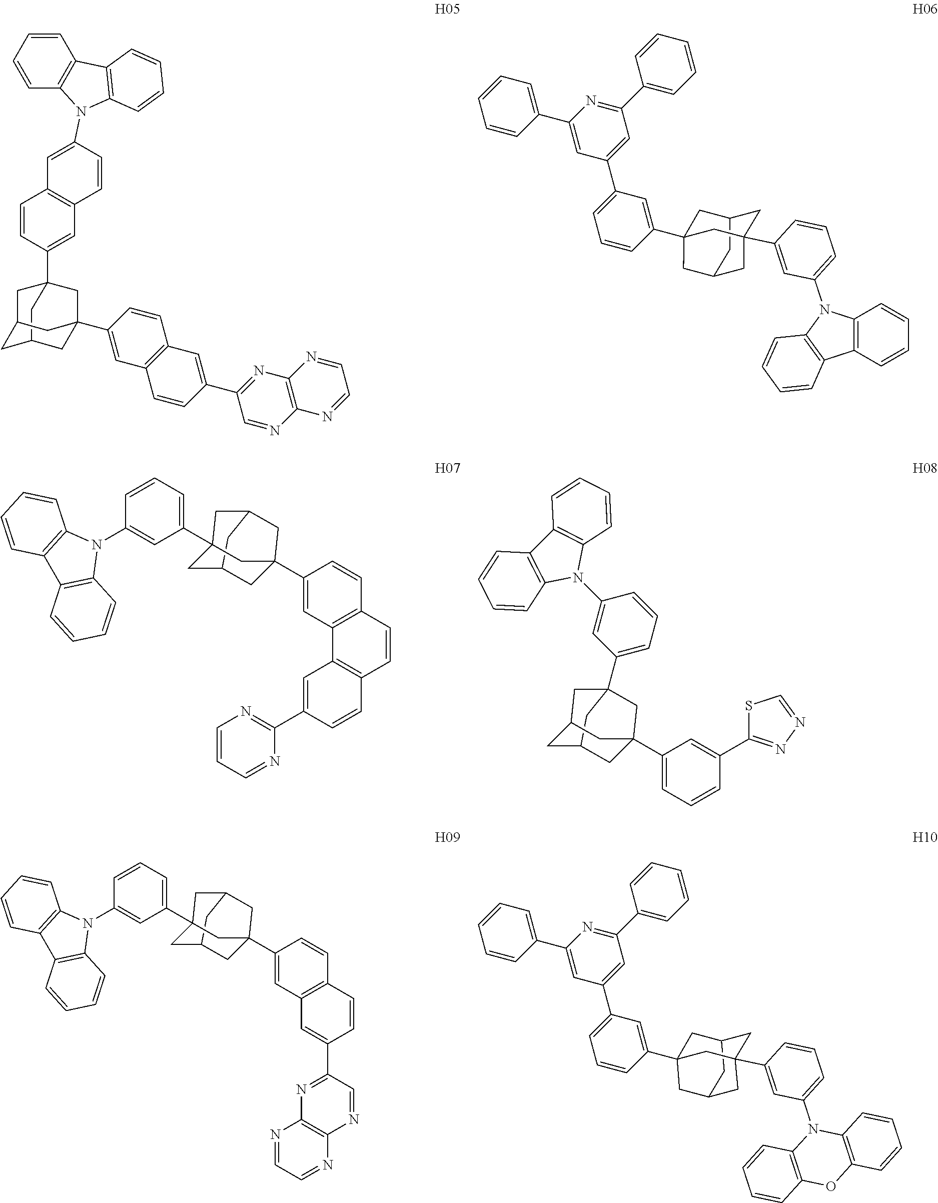

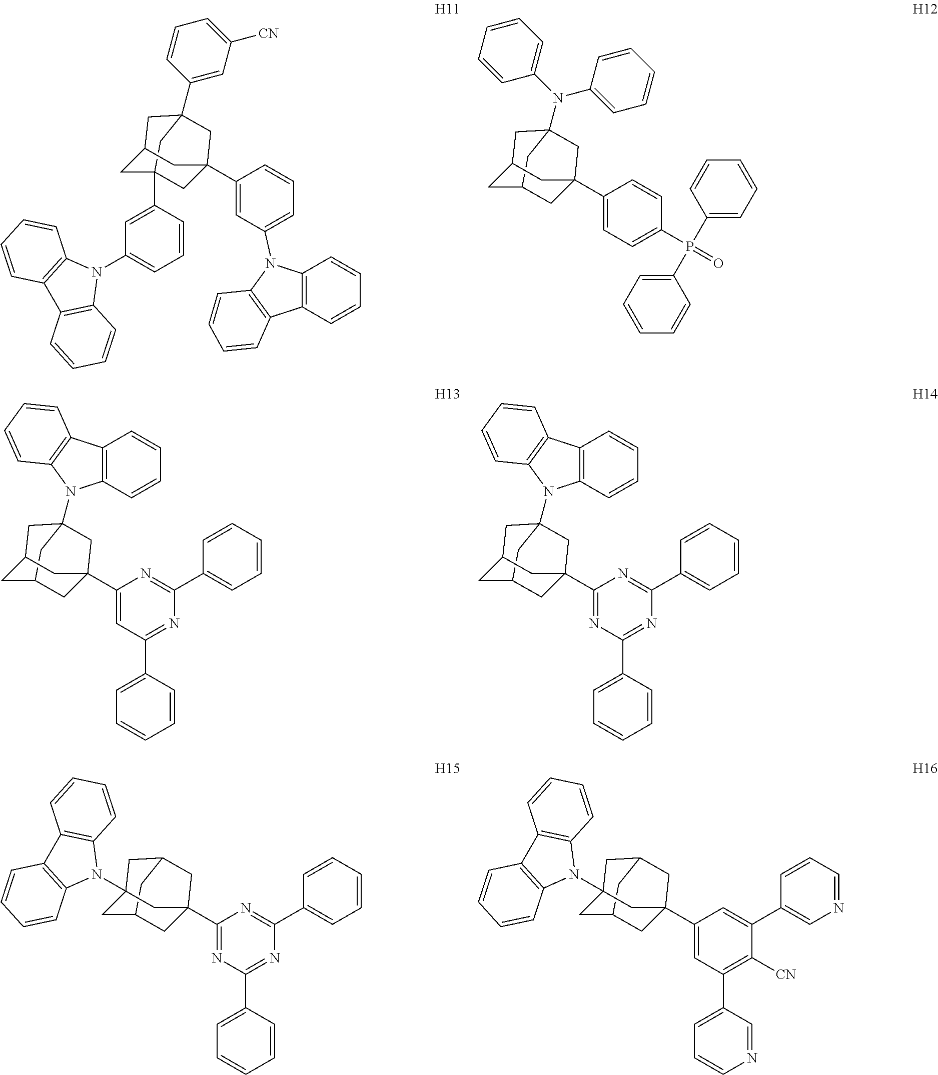

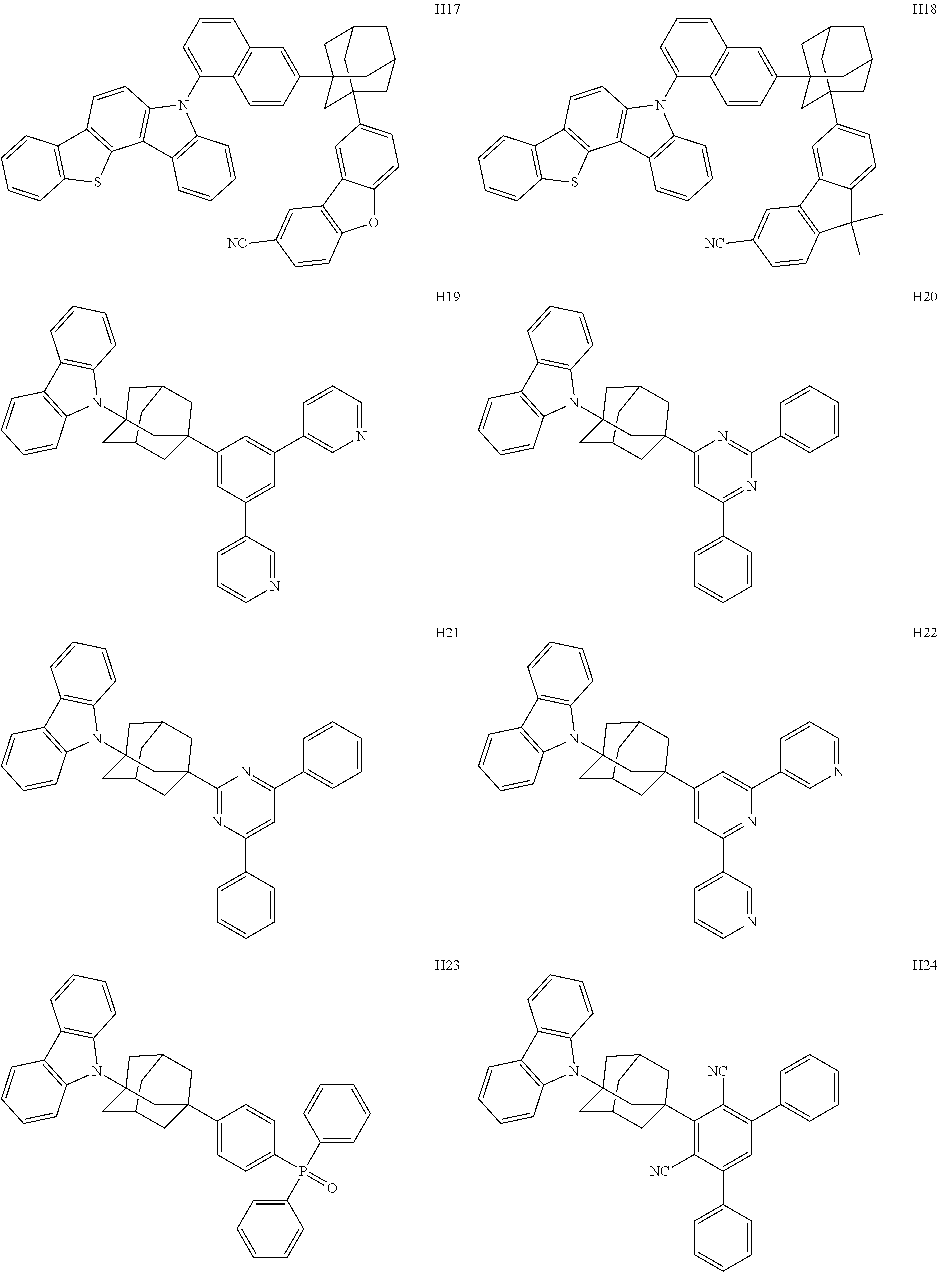

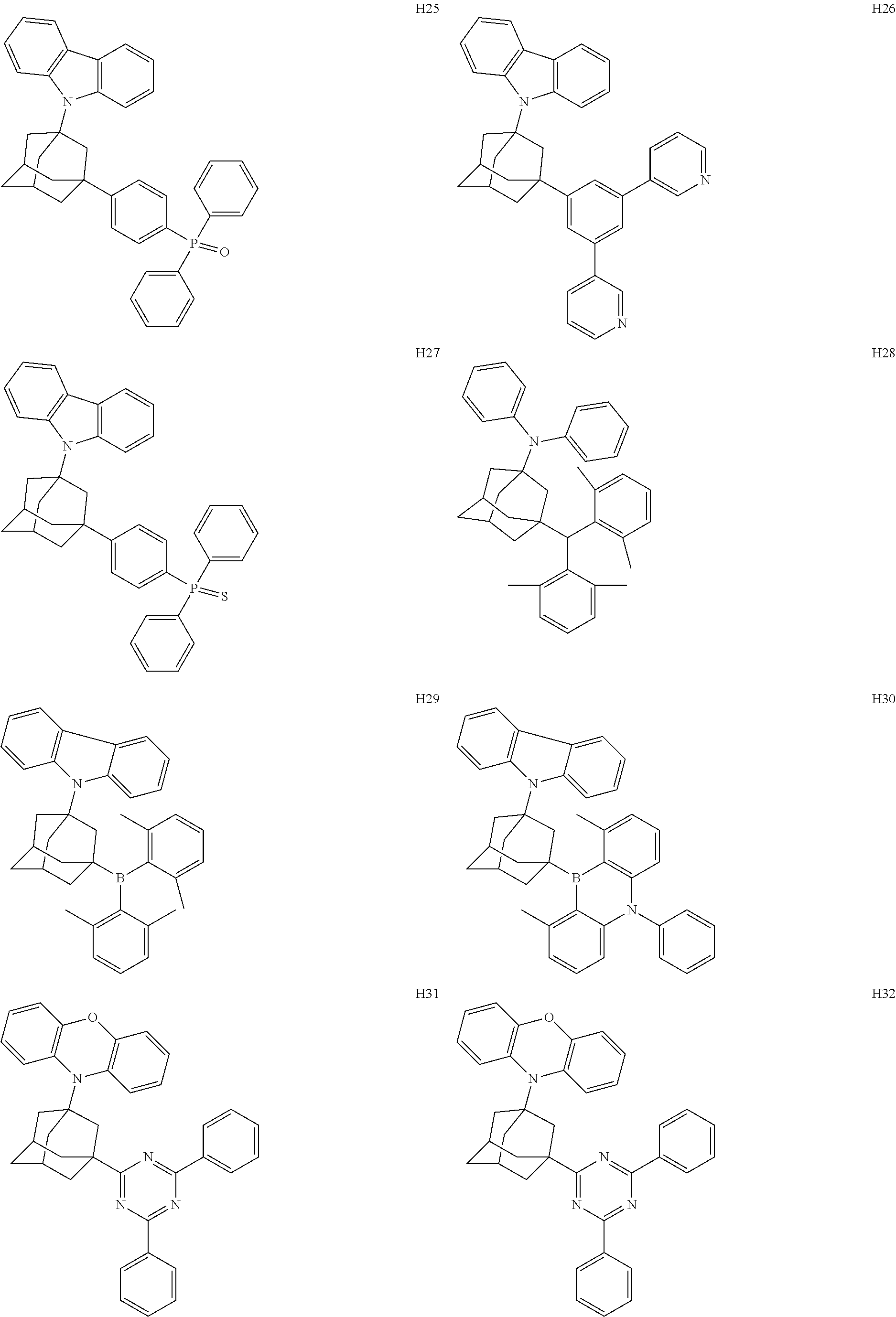

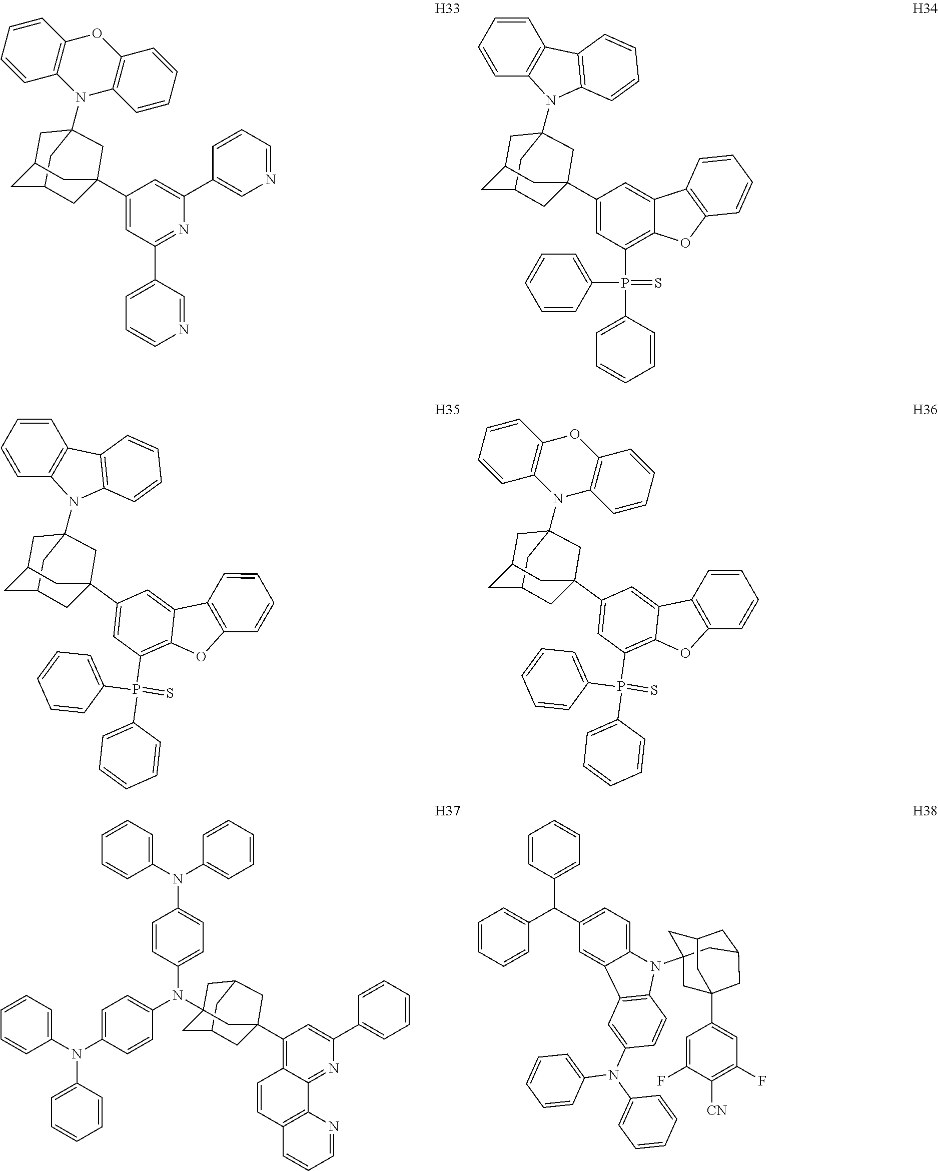

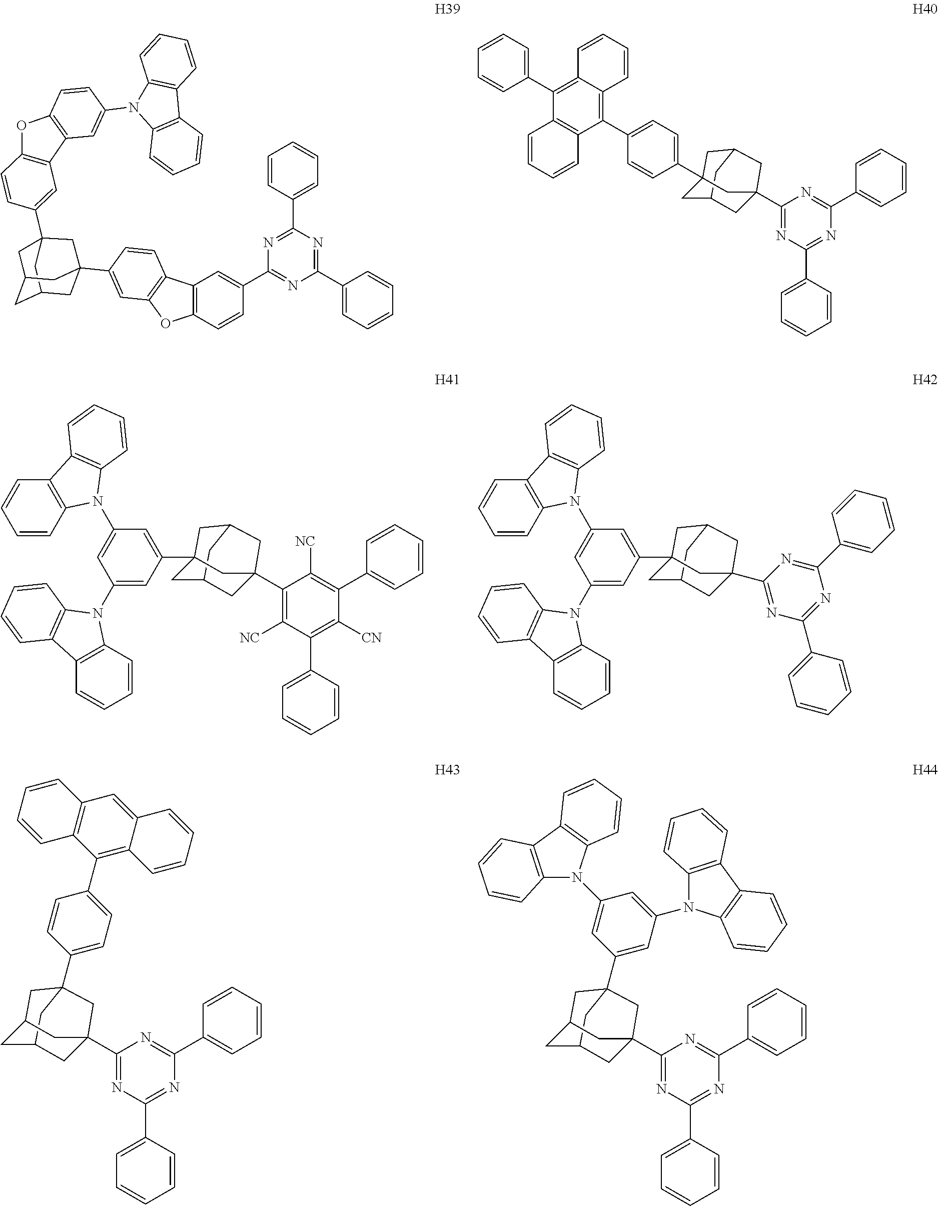

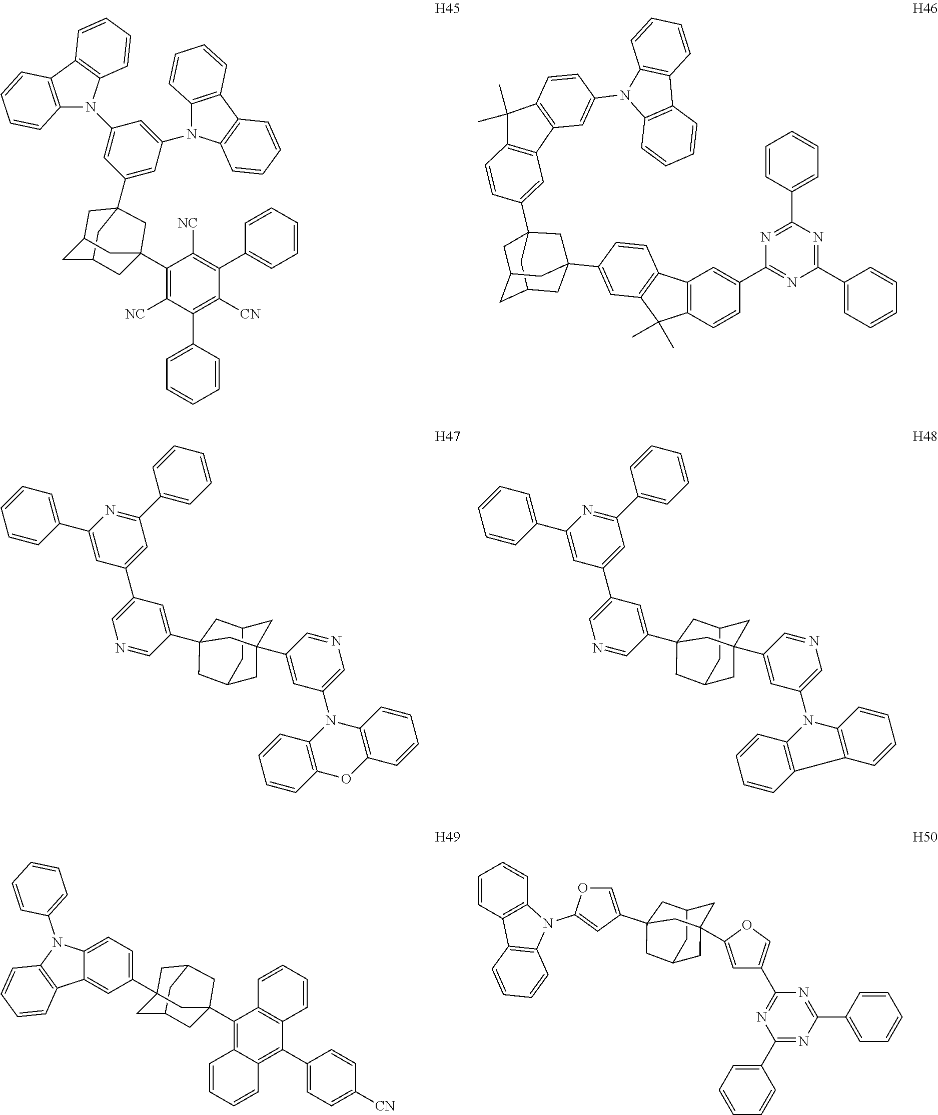

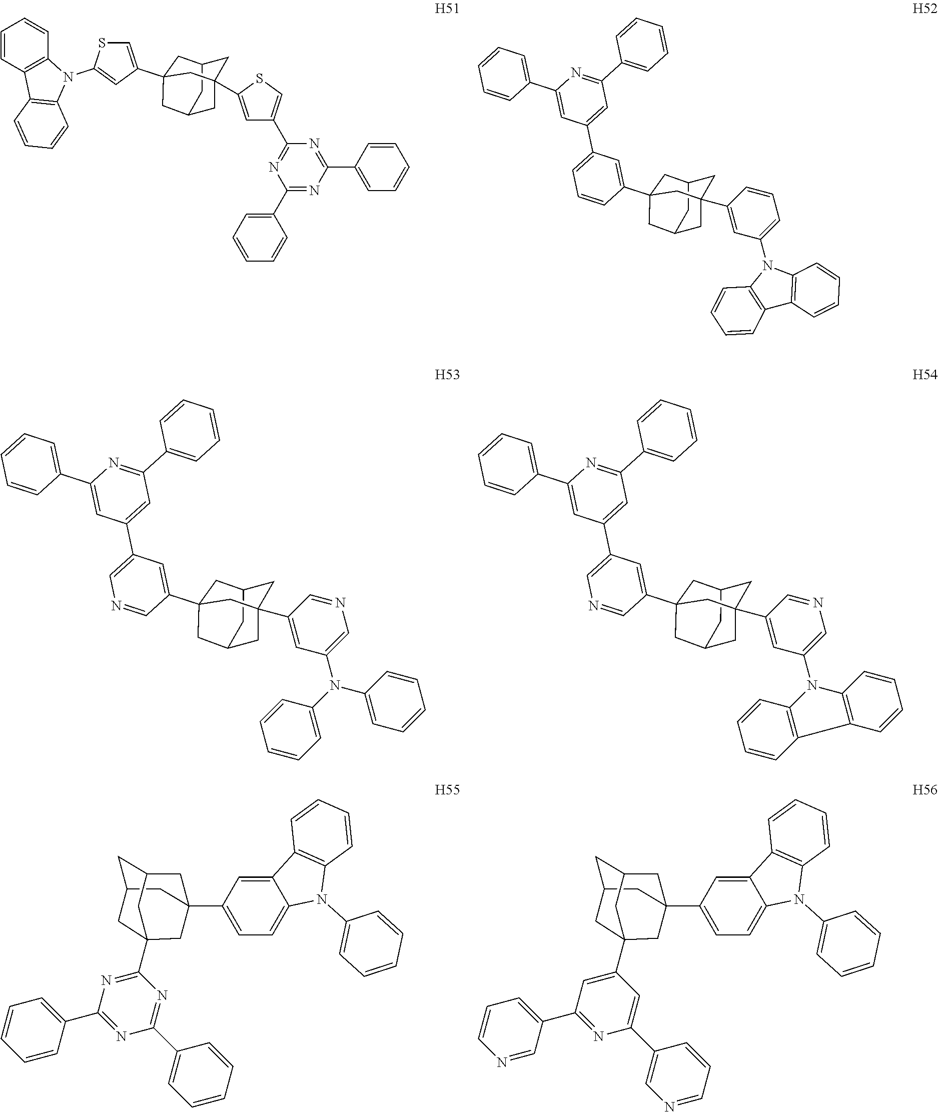

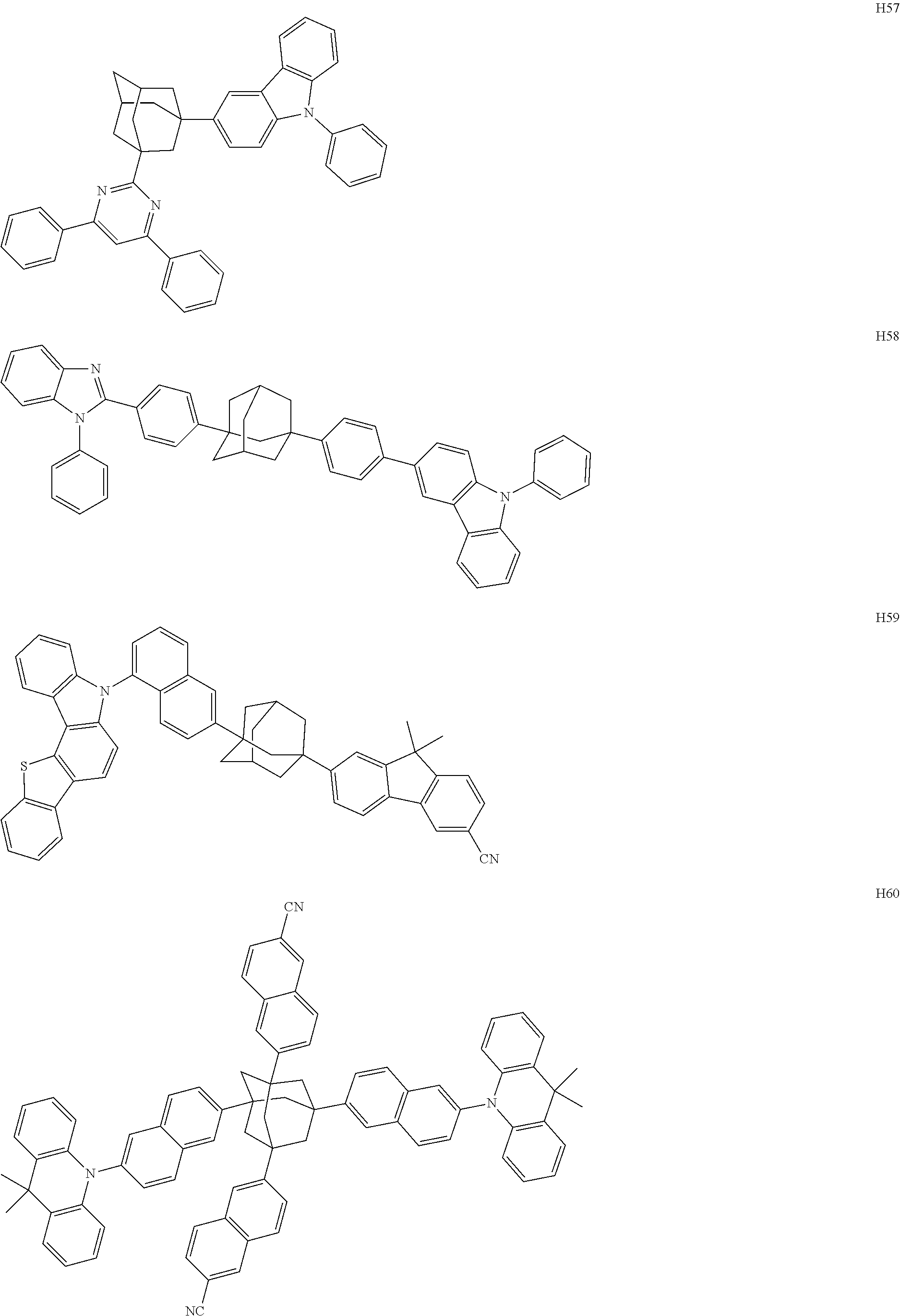

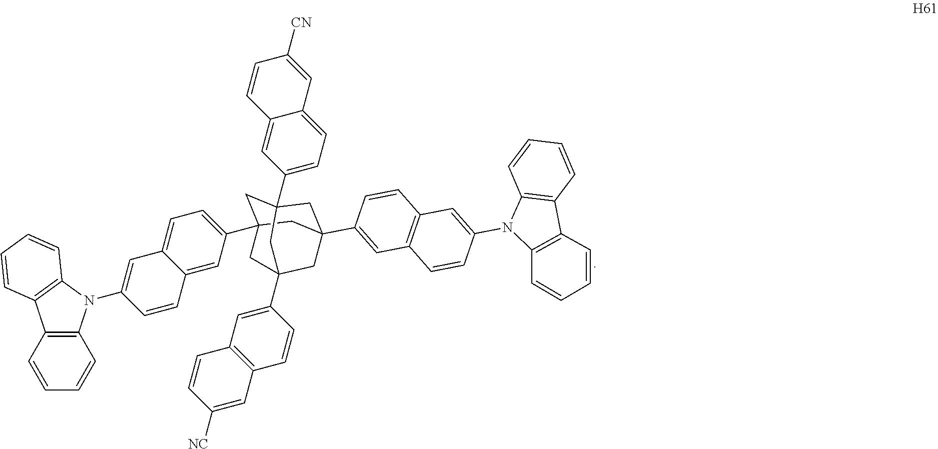 [SMILES: N#Cc1ccc2cc(C34CC5(c6ccc7cc(C#N)ccc7c6)CC(c6ccc7cc(-n8c9ccccc9c9ccccc98)ccc7c6)(C3)CC(c3ccc6cc(-n7c8ccccc8c8ccccc87)ccc6c3)(C4)C5)ccc2c1]

16. A display panel, comprising an organic light-emitting device, wherein the organic light-emitting device comprises an anode, a cathode arranged opposite to the anode, and a light-emitting layer disposed between the anode and the cathode, the light-emitting layer comprising a host material and a guest material, wherein the host material of the light-emitting layer comprises one or more of compounds according to claim 1.

17. The display panel according to claim 16, wherein the light-emitting layer is a blue light-emitting layer, and the host material is a host material of the blue light-emitting layer.

18. The display panel according to claim 16, wherein the host material has a higher singlet energy level S1 than the guest material, and a difference between the singlet energy level S1 of the host material and the singlet energy level S1 of the guest material is less than 0.8 eV; and
the host material has a higher triplet energy level T1 than the guest material, and a difference between the triplet energy level T1 of the host material and the triplet energy level T1 of the guest material is less than 0.4 eV.

19. The display panel according to claim 16, wherein the organic light-emitting device further comprises one or more layers selected from the group consisting of a hole injection layer, a hole transmission layer, an electron blocking layer, a hole blocking layer, an electron transmission layer, and an electron injection layer.

20. A display apparatus, comprising the display panel according to claim 16.
